(19) United States
(12) Patent Application Publication
(10) Pub. No.: US 2023/0231071 A1
(43) Pub. Date: Jul. 20, 2023

(54) APPARATUS AND METHOD FOR FABRICATING DISPLAY PANEL

(71) Applicant: SAMSUNG DISPLAY CO., LTD., Yongin-si (KR)

(72) Inventors: Hae Yun CHOI, Hwaseong-si (KR); Min Woo KIM, Hwaseong-si (KR); Dae Ho SONG, Hwaseong-si (KR); Tae Hee LEE, Hwaseong-si (KR); Joo Woan CHO, Seongnam-si (KR)

(21) Appl. No.: 18/146,972

(22) Filed: Dec. 27, 2022

(30) Foreign Application Priority Data
Jan. 20, 2022 (KR) 10-2022-0008500

(51) Int. Cl. H01L 33/00

(52) U.S. Cl. CPC H01L 33/005; H01L 2933/0025; H10K 71/50

(57) ABSTRACT

An apparatus for fabricating a display panel includes: a chamber; a first process driver configured to sequentially perform dispensing and coating processes on a display substrate or a light-emitting diode substrate in an internal processing space of the chamber; a second process driver configured to selectively perform at least one process selected from among moving, dipping, laminating, bonding, and laser irradiating processes on the display substrate or the light-emitting diode substrate; and a third process driver where the dipping and laminating processes on the display substrate or the light-emitting diode substrate are performed.

### CROSS-REFERENCE TO RELATED APPLICATION

This application claims priority from to and the benefit of Korean Patent Application No. 10-2022-0008500 filed on Jan. 20, 2022, in the Korean Intellectual Property Office, the entire content of which is herein incorporated by reference.

### BACKGROUND

### 1. Field

One or more embodiments of the present disclosure relate to an apparatus and a method for fabricating a display panel.

### 2. Description of the Related Art

Display devices become more and more important as multimedia technology evolves. Accordingly, a variety of types (or kinds) of display devices such as organic light-emitting display (OLED) devices and/or liquid-crystal display (LCD) devices are currently used.

Display devices include a display panel such as a light-emitting display panel and/or a liquid-crystal display panel for displaying images. Among them, light-emitting display panel may include light-emitting diodes (LEDs). Light-emitting diodes may include an organic light-emitting diode using an organic material as a luminescent material, and an inorganic light-emitting diode using an inorganic material as a luminescent material.

To fabricate a display panel using inorganic light-emitting diodes as light-emitting diodes, apparatuses for precisely (or suitably) disposing micro LEDs on the substrate of the display panel should be developed.

### SUMMARY

Aspects of embodiments of the present disclosure provide for an apparatus and a method for fabricating a display panel, by which light-emitting diodes can be easily (or suitably) moved from a light-emitting diode substrate to a circuit substrate of a display panel.

Aspects of embodiments of the present disclosure provide for an apparatus and a method for fabricating a display panel, by which a light-emitting diode substrate and a circuit substrate of a display panel can be selectively pre-processed in the same space of a chamber, and light-emitting diodes can be moved and attached to the circuit substrate of the display panel in the same space.

It should be noted that objects of the present disclosure are not limited to the above-mentioned object; and other objects of the present disclosure will be apparent to those skilled in the art from the following descriptions.

According to one or more embodiments of the disclosure, an apparatus for fabricating a display panel may include: a chamber; a first process driver configured to sequentially perform a dispensing process and a coating process on a display substrate or a light-emitting diode substrate in an internal processing space of the chamber; a second process driver configured to selectively perform at least one process selected from among a moving process, a dipping process, a laminating process, a bonding process, and a laser irradiating process on the display substrate or the light-emitting diode substrate; and a third process driver where at least one selected from the dipping and laminating processes may be performed on the display substrate or the light-emitting diode substrate.

In one or more embodiments, the first process driver may include a first loading unit at a lower portion (e.g., on one side) of the internal processing space inside the chamber, the display substrate or the light-emitting diode substrate being configured to be loaded on the first loading unit; at least one dispenser configured to perform the dispensing process on the display substrate or the light-emitting diode substrate loaded on the first loading unit; and at least one coating device configured to perform the coating process on the display substrate or the light-emitting diode substrate.

In one or more embodiments, the at least one dispenser and the at least one coating device may be on a same set path in the internal processing space inside the chamber and may be configured to sequentially move along the path to sequentially perform the dispensing process and the coating process.

In one or more embodiments, the at least one dispenser may be formed integrally with a dispenser moving member that is configured to move along a set path in the internal processing space inside the chamber, and the at least one dispenser may be configured to perform the dispensing process on the display substrate or the light-emitting diode substrate loaded on the first loading unit while moving along the path of the dispenser moving member.

In one or more embodiments, the at least one coating device may be formed integrally with a coating device moving member that is configured to move along a same path as the dispenser moving member, and is configured to perform the coating process on the display substrate or the light-emitting diode substrate while moving along the path of the coating device moving member.

In one or more embodiments, the dispenser moving member and the coating device moving member may be integrally formed on a set path in the internal processing space inside the chamber, and wherein the at least one dispenser and the at least one coating device may be formed integrally with the dispenser moving member and the coating device moving member, respectively, to sequentially perform the dispensing and the coating processes.

In one or more embodiments, the second process driver may be configured to be movable along a set path at an upper portion of the internal processing space inside the chamber, and wherein the second process driver may be configured to selectively perform the at least one process selected from among a moving process, a dipping process, a laminating process, a bonding process, and a laser irradiating process with respect to a display substrate or a light-emitting diode substrate different from the display substrate or the light-emitting diode substrate on which the dispensing and coating processes are performed in the first process driver.

In one or more embodiments, the second process driver may include a substrate laminating module configured to hold a rear side of the display substrate or the light-emitting diode substrate to vertically or horizontally move the display substrate or the light-emitting diode substrate in the internal processing space inside the chamber; a module transfer mechanism configured to vertically or horizontally move the substrate laminating module along a predetermined path in the internal processing space inside the chamber; at least one camera module formed integrally with the substrate laminating module or the module transfer mechanism and configured to align the display substrate with the light-emitting diode substrate; and at least one laser module formed integrally with the substrate laminating module or the module transfer mechanism and configured to irradiate laser light to the display substrate and the light-emitting diode substrate laminated together.

In one or more embodiments, the substrate laminating module may be configured to laminate the display substrate or the light-emitting diode substrate with the display substrate or the light-emitting diode substrate loaded on the first process driver or another display substrate or another light-emitting diode substrate loaded on the third process driver.

In one or more embodiments, the substrate laminating module may be configured to vertically move the display substrate or the light-emitting diode substrate in the internal processing space inside the chamber to dip the display substrate or the light-emitting diode substrate in a dipping solution of the third process driver, and to laminate the display substrate or the light-emitting diode substrate after the dipping process with another display substrate or another light-emitting diode substrate loaded on the first process driver.

In one or more embodiments, the substrate laminating module may be configured to vertically move the display substrate or the light-emitting diode substrate in the internal processing space inside the chamber to dip the display substrate or the light-emitting diode substrate in a dipping solution of the third process driver, and to laminate the display substrate or the light-emitting diode substrate after the dipping process with another display substrate or another light-emitting diode substrate loaded on the third process driver.

In one or more embodiments, the third process driver may include a container configured to accommodate a dipping solution in which the display substrate or the light-emitting diode substrate is configured to be dipped by the second process driver; and a second loading unit where another display substrate or another light-emitting diode substrate is configured to be loaded and fixed and where the display substrate or the light-emitting diode substrate dipped by the second process driver is configured to be laminated with the other display substrate or the other light-emitting diode substrate loaded and fixed in the second loading unit.

According to one or more embodiments of the disclosure, a method for fabricating a display panel may include: loading a display substrate or a light-emitting diode substrate onto a first loading unit of a first process driver in a chamber; performing a dispensing process and a coating process on the display substrate or the light-emitting diode substrate loaded on the first loading unit; moving another display substrate or another light-emitting diode substrate via a second process driver in the chamber; aligning and laminating the other display substrate or the other light-emitting diode substrate with the display substrate or the light-emitting diode substrate loaded on the first loading unit to form a laminate structure comprising one display substrate and one light-emitting diode substrate; and attaching and fixing light-emitting diodes to the one display substrate of the laminate structure by irradiating a laser to the laminate structure.

In one or more embodiments, the performing the dispensing process and the coating process may include dispensing an adhesive composition onto the display substrate or the light-emitting diode substrate loaded on the first loading unit via at least one dispenser at a lower portion on one side of a processing space inside the chamber; and performing the coating process on the display substrate or the light-emitting diode substrate via at least one coating device.

In one or more embodiments, the performing the coating process may include performing the coating process on the display substrate or the light-emitting diode substrate while moving the at least one coating device in a same path as the at least one dispenser.

In one or more embodiments, the performing the dispensing process and the coating process may include sequentially performing the dispensing process and the coating process while concurrently moving the at least one dispenser and the at least one coating device, the at least one dispenser being formed integrally with a dispenser moving member.

In one or more embodiments, the aligning and laminating the other display substrate or the other light-emitting diode substrate with the display substrate or the light-emitting diode substrate loaded onto the first loading unit may include moving the other display substrate or the other light-emitting diode substrate vertically or horizontally in the internal processing space inside the chamber; aligning the display substrate and the other light-emitting diode substrate, or aligning the light-emitting diode substrate and the other display substrate, using at least one camera module; and laminating the display substrate or the light-emitting diode substrate with the other light-emitting diode substrate or the other display substrate, respectively, and irradiating laser light with at least one laser module.

In one or more embodiments, the method may further include performing a dipping process on the other display substrate or the other light-emitting diode substrate via the second process driver; and laminating the dipped display substrate or the dipped light-emitting diode substrate with the corresponding display substrate or the corresponding light-emitting diode substrate loaded on the first loading unit.

In one or more embodiments, the method may further include performing a dipping process on the other display substrate or the other light-emitting diode substrate via the second process driver; loading the display substrate or the light-emitting diode substrate onto a second loading unit of a third process driver; laminating the dipped display substrate or the dipped light-emitting diode substrate with the display substrate or the light-emitting diode substrate loaded onto the second loading unit to form a laminate structure comprising one display substrate and one light-emitting diode substrate; and attaching and fixing light-emitting diodes to the one display substrate of the laminate structure by irradiating a laser onto the laminate structure.

In one or more embodiments, the aligning and laminating the other display substrate or the other light-emitting diode substrate with the display substrate or the light-emitting diode substrate loaded onto the second loading unit may include aligning the display substrate loaded onto the second loading unit with the dipped light-emitting diode substrate using at least one camera module; and laminating the display substrate with the dipped light-emitting diode substrate and irradiating laser light with at least one laser module.

According to one or more embodiments of the present disclosure, an apparatus for fabricating a display panel allows a light-emitting diode substrate and a circuit substrate of a display panel to be selectively pre-processed in the same space inside a single chamber, and the substrates to be laminated, so that the time and cost for fabricating the display panel can be saved.

In addition, fabrication processes may be carried out such as dispensing, coating, dipping, aligning, laminating, bonding, laser irradiating and moving on each substrate in the same space inside a single chamber. Accordingly, it is possible to reduce the fabrication space and increase the fabrication efficiency.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in more detail embodiments thereof with reference to the attached drawings, in which:

FIG. 1 is a plan view of a display device according to one or more embodiments of the present disclosure.

FIG. 2 is a plan view schematically showing emission areas of pixels according to one or more embodiments.

FIG. 3 is a plan view schematically showing emission areas of pixels according to one or more other embodiments.

FIG. 4 is an equivalent circuit diagram of each of pixels according to one or more embodiments of the present disclosure.

FIG. 5 is an equivalent circuit diagram of each of pixels according to one or more other embodiments of the present disclosure.

FIG. 6 is a cross-sectional view schematically showing line A-A′ of FIG. 2 according to one or more embodiments.

FIG. 7 is an enlarged view showing the first emission area of FIG. 6.

FIG. 8 is a cross-sectional view showing in more detail the light-emitting diodes of FIG. 7.

FIG. 9 is a side view showing an apparatus for fabricating a display panel according to one or more embodiments.

FIG. 10 is a flowchart for illustrating a method for fabricating a display panel using the apparatus of FIG. 9.

FIG. 11 is a side view showing a dispensing and coating process of a pixel circuit substrate using the apparatus of FIG. 9.

FIG. 12 is a side view showing a dipping process of a light-emitting diode substrate using the apparatus of FIG. 9.

FIG. 13 is a side view showing a process of laminating a pixel circuit substrate with a light-emitting diode arrangement substrate (hereinafter, also referred to as “light-emitting diode substrate”) using the apparatus of FIG. 9.

FIGS. 14-16 are cross-sectional views of a pixel circuit substrate for illustrating a process of attaching light-emitting diodes to the pixel circuit substrate by the apparatus of FIG. 9.

FIG. 17 is a flowchart according to one or more other embodiments for illustrating a method for fabricating a display panel using the apparatus of FIG. 9.

FIG. 18 is a side view according to one or more other embodiments showing a dipping process of a light-emitting diode substrate using the apparatus of FIG. 9.

FIG. 19 is a side view according to one or more other embodiments showing a process of laminating a pixel circuit substrate with a light-emitting diode arrangement substrate using the apparatus of FIG. 9.

FIG. 20 is a cross-sectional view of a pixel circuit substrate for illustrating a process of fabricating a pixel circuit substrate after arrangement of light-emitting diodes.

### DETAILED DESCRIPTION

The present disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate (e.g., without any intervening layers therebetween), or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present invention described herein may be implemented utilizing any suitable hardware, firmware (e.g. an application-specific integrated circuit), software, or a combination of software, firmware, and hardware. For example, the various components of the apparatus may be formed on one integrated circuit (IC) chip or on separate IC chips. Further, the various components of the apparatus may be implemented on a flexible printed circuit film, a tape carrier package (TCP), a printed circuit board (PCB), or formed on one substrate. Further, the various components of the apparatus may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

Hereinafter, embodiments of the present disclosure will be described with reference to the accompanying drawings.

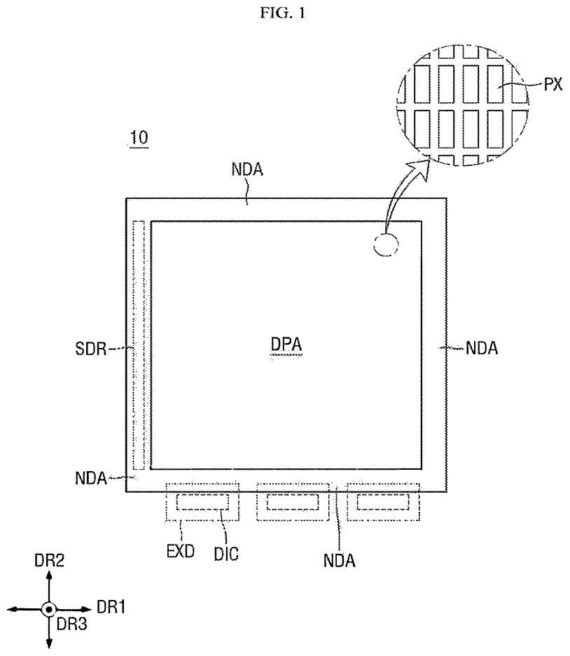

FIG. 1 is a plan view of a display device according to one or more embodiments of the present disclosure.

Referring to FIG. 1, a display device 10 according to one or more embodiments of the present disclosure may be applied to, a smart phone, a mobile phone, a tablet PC, a personal digital assistant (PDA), a portable multimedia player (PMP), a television set, a game machine, a wristwatch-type electronic device, a head-mounted display, a personal computer monitor, a laptop computer, a car navigation system, a car instrument cluster, a digital camera, a camcorder, an outdoor billboard, an electronic billboard, various medical apparatuses, various home appliances such as a refrigerator and/or a laundry machine, Internet of things (IoT) devices, etc. In the following description, a television is described as an example of the display device. TV may have a high resolution or ultra high resolution such as HD, UHD, 4K and/or 8K.

In addition, the display device 10 according to the embodiments may be variously classified by the way in which images are displayed. Examples of the classification of display devices may include an organic light-emitting display device (OLED), an inorganic light-emitting display device (inorganic EL), a quantum-dot light-emitting display device (QED), a micro LED display device (micro-LED), a nano LED display device (nano-LED), a plasma display device (PDP), a field emission display device (FED), a cathode ray display device (CRT), a liquid-crystal display device (LCD), an electrophoretic display device (EPD), etc. In the following description, a micro LED display device will be described as an example of the display device. The micro LED display device will be simply referred to as a display device unless it is necessary to discern them. It should be understood, however, that the embodiments of the present disclosure are not limited to the micro LED display devices, and any other suitable display device, listed above and/or known in the art, may be employed without departing from the scope of the present disclosure.

In the drawings, a first direction DR1 refers to the horizontal direction of a display device 10, a second direction DR2 refers to the vertical direction of the display device 10, and a third direction DR3 refers to the thickness direction of the display device 10. As used herein, the terms “left,” “right,” “upper” and “lower” sides indicate relative positions when the display panel 10 is viewed from the top. For example, the right side refers to one side in the first direction DR1, the left side refers to the other side in the first direction DR1, the upper side refers to one side in the second direction DR2, and the lower side refers to the other side in the second direction DR2. In addition, the upper portion refers to the side indicated by the arrow of the third direction DR3, while the lower portion refers to the opposite side in the third direction DR3. According to one or more embodiments of the present disclosure, the display device 10 may have a circular, elliptical or quadrangular shape, e.g., a square shape when viewed from the top. When the display device 10 is a television, it may have a rectangular shape in which the longer sides are located in the horizontal direction. It should be understood, however, that the present disclosure is not limited thereto. The longer sides may be positioned in the vertical direction. In one or more embodiments, the display device 1 may be installed rotatably (e.g., capable of being rotated) so that the longer sides are positioned in the horizontal or vertical direction variably.

The display device 10 may include a display area DPA and a non-display area NDA. The display area DPA may be an active area where images are displayed. The display area DPA may have, but is not limited to, a square shape similar to the general shape of the display device 10 when viewed from the top. It may have a circular shape or an elliptical shape.

The display area DPA may include a plurality of pixels PX. The plurality of pixels PX may be arranged in a matrix. The shape of each of the pixels PX may be, but is not limited to, a rectangle or a square when viewed from the top. Each of the pixels PX may have a diamond shape having sides inclined with respect to a side of the display device 10. The plurality of pixels PX may include different color pixels PX. For example, the plurality of pixels PX may include, but is not limited to, a red first color pixel PX, a green second color pixel PX, and a blue third color pixel PX. The color pixels PX may be arranged in stripes and/or Pentile®/PENTILE® matrix alternately with each other (PENTILE® is a registered trademark owned by Samsung Display Co., Ltd.).

The non-display area NDA may be provided around the display area DPA. The non-display area NDA may surround the display area DPA entirely or partially. The display area DA may have a variety of suitable shapes such as a circle and/or a square. The non-display area NDA may surround the display area DA. The non-display area NDA may form the bezel of the display device 10.

In the non-display areas NDA, a driving circuit and/or a driving element for driving the display area DPA may be provided. According to one or more embodiments of the present disclosure, pad areas may be located on the display substrate of the display device 10 in the non-display area NDA adjacent to a first side (e.g., the lower side in FIG. 1) of the display device 10, and external devices EXD may be mounted on pad electrodes of the pad areas. Examples of the external devices EXD may include a connection film, a printed circuit board, a driver chip DIC, a connector, a line connection film, etc. A scan driver SDR formed directly on the display substrate of the display device 10 and/or the like may be provided in the non-display area NDA adjacent to a second side (e.g., the left side in FIG. 1) of the display device 10.

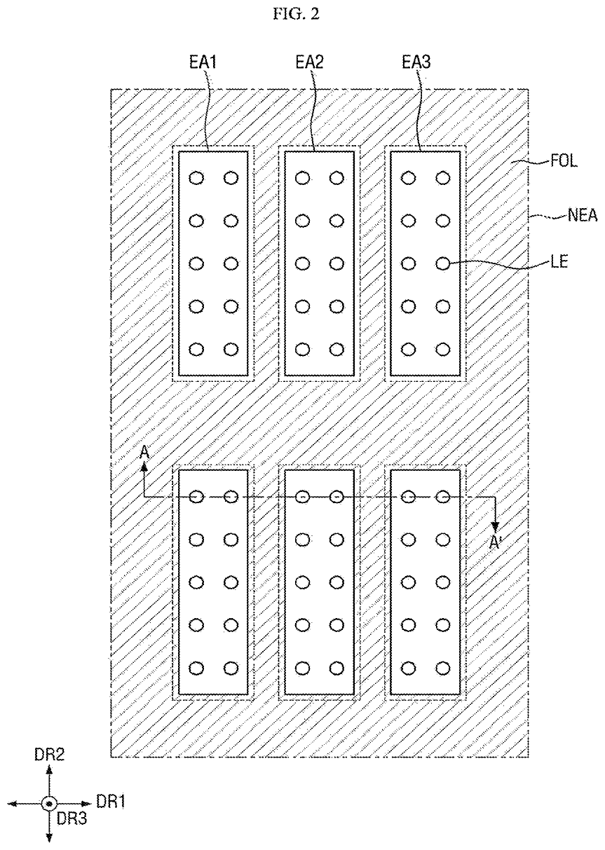

FIG. 2 is a plan view showing emission areas of pixels according to one or more embodiments.

Referring to FIG. 2, the plurality of pixels PX may be arranged in a matrix, and the plurality of pixels PX may be sorted into a first color pixel PX of red color, a second color pixel PX of green color, and a third color pixel PX of blue color. In some embodiments, a fourth color pixel PX of white color may be further included.

The pixel electrode of the first color pixel PX may be provided in a first emission area EA1 and may be extended to a non-emission area NEA at least partially. The pixel electrode of the second color pixel PX may be provided in a second emission area EA2 and may be extended to the non-emission area NEA at least partially. The pixel electrode of the third color pixel PX may be provided in a third emission area EA3 and may be extended to the non-emission area NEA at least partially. The pixel electrode of each of the pixels PX may pass through at least one insulating layer to be connected with one switching element included in the respective pixel circuit.

A plurality of light-emitting diodes LE are provided on the pixel electrode of the first emission area EA1, the pixel electrode of the second emission area EA2, and the pixel electrode of the third emission area EA3. In some embodiments, the light-emitting diodes LE are provided in each of the first emission area EA1, the second emission area EA2 and the third emission area EA3. A red first color filter, a green second color filter, and blue third color filter may be provided on the first emission area EA1, the second emission area EA2, and the third emission area EA3, respectively, in which the plurality of light-emitting diodes LE is provided. A first organic layer FOL may be provided in the non-emission area NEA.

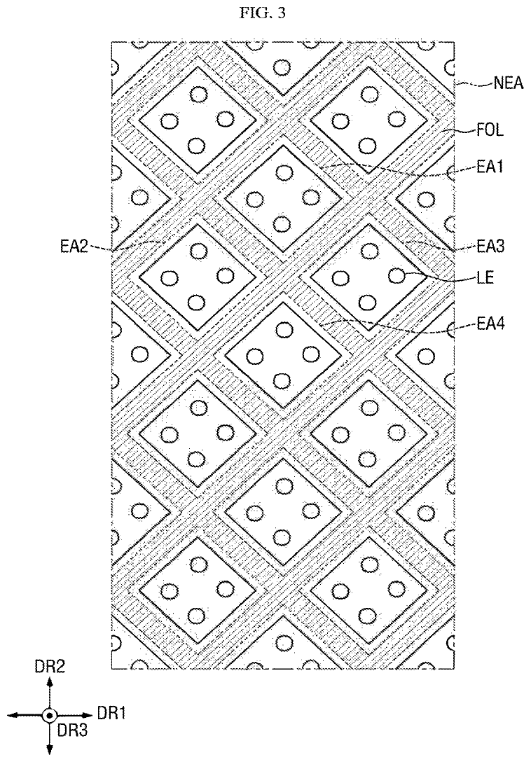

FIG. 3 is a plan view showing emission areas of pixels according to other one or more embodiments.

Referring to FIG. 3, the shape of the pixels PX is not limited to a rectangular or square shape when viewed from the top, but may be a diamond shape in which the sides are inclined with respect to one side of the display device 10 to form a Pentile®/PENTILE® matrix structure. Accordingly, in the pixels PX of the Pentile®/PENTILE® matrix structure, the first emission area EA1 of the first color pixel PX, the second emission area EA2 of the second color pixel PX, the third emission area EA3 of the third color pixel PX and the fourth emission area EA4 of the pixel PX of one of the first to third colors may be formed in a diamond shape.

The first to fourth emission areas EA1 to EA4 of the pixels PX may have the same size or area or different sizes or areas. In some embodiments, the numbers of light-emitting diodes LE formed in the first to fourth emission areas EA1 to EA4 may all be equal or different from one another.

The area of the first emission area EA1, the area of the second emission area EA2, the area of the third emission area EA3, and the area of the fourth emission area EA4 may all be substantially equal. It should be understood, however, that the present disclosure is not limited thereto. The areas may be different from one another. The distance between the first emission area EA1 and the second emission area EA2 adjacent to each other, the distance between the second emission area EA2 and the third emission area EA3 adjacent to each other, the distance between the first emission area EA1 and the third emission area EA3 adjacent to each other, and the distance between the third emission area EA3 and the fourth emission area EA4 may all be substantially equal or may be different from one another. However, the embodiments of the present disclosure are not limited thereto.

The first emission area EA1 may emit first light, the second emission area EA2 may emit second light, the third emission area EA3 may emit third light, and the fourth emission area EA4 may emit the same light as one of the first to third lights. However, the embodiments of the present disclosure are not limited thereto. For example, the first emission area EA1 may emit the second light, the second emission area EA2 may emit the first light, and the third and fourth emission areas EA3 and EA4 may emit the third light. In one or more embodiments, at least one of the first to fourth emission areas EA1 to EA4 may emit fourth light. The fourth light may be light of white or yellow wavelength range. For example, the main peak wavelength of the fourth light may range approximately from 550 nm to 600 nm, but embodiments of the present disclosure are not limited thereto.

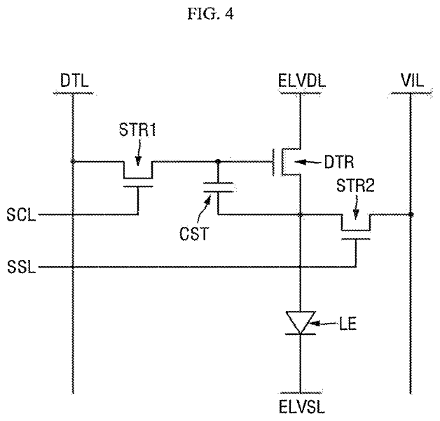

FIG. 4 is an equivalent circuit diagram of each of pixels according to one or more embodiments of the present disclosure.

Referring to FIG. 4, each of the pixels PX may include three transistors DTR, STR1 and STR2 and one storage capacitor CST for allowing the light-emitting diodes LE to emit light. The driving transistor DTR adjusts a current flowing from the first supply voltage line ELVDL from which the first supply voltage is applied to one light-emitting diode LE according to the voltage difference between a gate electrode and a source electrode. The gate electrode of the driving transistor DTR may be connected to a first electrode of the first transistor STR1, the source electrode may be connected to a first electrode of one light-emitting diode LE, and the drain electrode may be connected to the first supply voltage line ELVDL from which the first supply voltage is applied.

The first transistor STR1 is turned on by a scan signal of a scan line SCL to connect a data line DTL with the gate electrode of the driving transistor DTR. A gate electrode of the first transistor STR1 may be connected to the scan line SCL, the first electrode thereof may be connected to the gate electrode of the driving transistor DTR, and a second electrode thereof may be connected to the data line DTL.

The second transistor STR2 may be turned on by a sensing signal of a sensing signal line SSL to connect the initialization voltage line VIL to the source electrode of the driving transistor DTR. A gate electrode of the second transistor ST2 may be connected to the sensing signal line SSL, a first electrode thereof may be connected to the initialization voltage line VIL, and a second electrode thereof may be connected to the source electrode of the driving transistor DTR.

According to one or more embodiments of the present disclosure, the first electrode of each of the first and second transistors STR1 and STR2 may be a source electrode while the second electrode thereof may be a drain electrode. It is, however, to be understood that the present disclosure is not limited thereto. The first electrode of each of the first and second switching transistors STR1 and STR2 may be a drain electrode while the second electrode thereof may be a source electrode.

The capacitor CST may be formed between the gate electrode and the source electrode of the driving transistor DTR. The storage capacitor CST stores a voltage difference between the gate voltage and the source voltage of the driving transistor DTR.

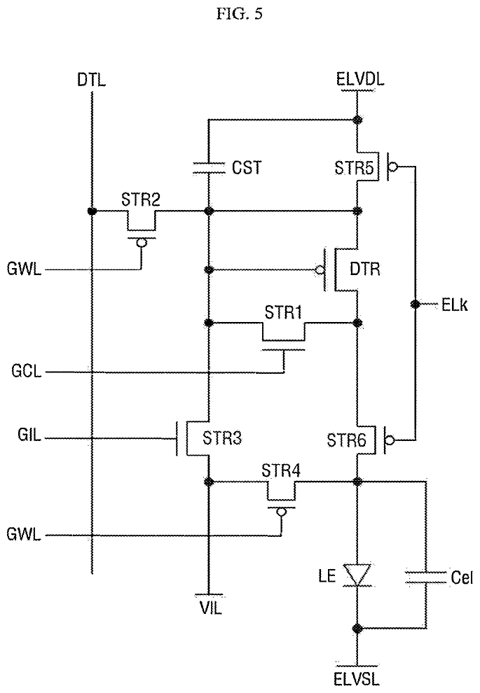

The driving transistor DTR and the first and second transistors STR1 and STR2 may be formed as thin-film transistors. Although FIG. 5 shows that each of the driving transistor DTR and the first and second switching transistors STR1 and STR2 is implemented as an n-type MOSFET (metal oxide semiconductor field effect transistor), it is to be noted that the present disclosure is not limited thereto. For example, the driving transistor DTR and the first and second switching transistors STR1 and STR2 may be implemented as p-type MOSFETs, or some of them may be implemented as n-type MOSFETs while the others may be implemented as p-type MOSFETs.

FIG. 5 is an equivalent circuit diagram of each of pixels according to other one or more embodiments of the present disclosure.

Referring to FIG. 5, each of the pixels PX may include a driving transistor DTR, switching elements, and a capacitor CST for allowing the light-emitting diodes LE to emit light. The switch elements may include first to sixth transistors STR1, STR2, STR3, STR4, STR5 and STR6.

The driving transistor DTR includes a gate electrode, a first electrode, and a second electrode. A drain-source current Ids (hereinafter referred to as “driving current”) of driving transistor DTR flowing between the first electrode and the second electrode is controlled according to the data voltage applied to the gate electrode.

The capacitor CST is formed between the second electrode of the driving transistor DTR and the second supply voltage line ELVSL. One electrode of the capacitor CST may be connected to the second electrode of the driving transistor DTR while the other electrode thereof may be connected to the second voltage supply line ELVSL.

The first to fourth transistors STR1, STR2, STR3, STR4 may be turned on by scan signals of scan lines GCL, GWL and GIL, and the fifth and sixth transistors STR5 and STR6 may be turned on by an emission control signal of an emission control line ELk.

Further, in an embodiment of the present disclosure, a capacitance Cel may be formed between the first electrode of the light-emitting diode LE and the second electrode of the light-emitting diode LE which is applied with a second supply voltage supplied via a second supply voltage line ELVSL.

When the first electrode of each of the first to sixth transistors STR1, STR2, STR3, STR4, STR5 and STR6 and the driving transistor DTR is the source electrode, the second electrode thereof may be the drain electrode. In some embodiments, when the first electrode of each of the first to sixth transistors STR1, STR2, STR3, STR4, STR5 and STR6 and the driving transistor DTR is the drain electrode, the second electrode thereof may be the source electrode.

The driving transistor DTR, the second transistor STR2, the fourth transistor STR4, the fifth transistor STR5 and the sixth transistor STR6 may be implemented as p-type MOSFETs while the first transistor STR1 and the third transistor STR3 may be implemented as n-type MOSFETs. In one or more embodiments, the first to sixth transistors STR1, STR2, STR3, STR4, STR5 and STR6 and the driving transistor DTR may be implemented as p-type metal oxide semiconductor field effect transistors (MOSFETs).

It should be noted that the equivalent circuit diagrams of the pixels according to the embodiments of the present disclosure are not limited to those illustrated in FIGS. 4 and 5. The equivalent circuit diagram of the pixel according to the embodiments of the present disclosure may be implemented as any suitable circuit structure other than that of the embodiments shown in FIGS. 4 and 5.

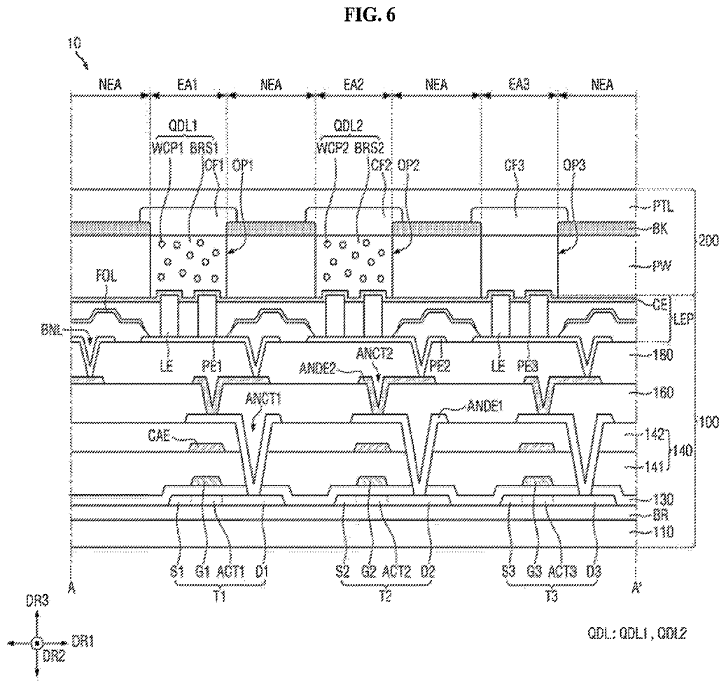

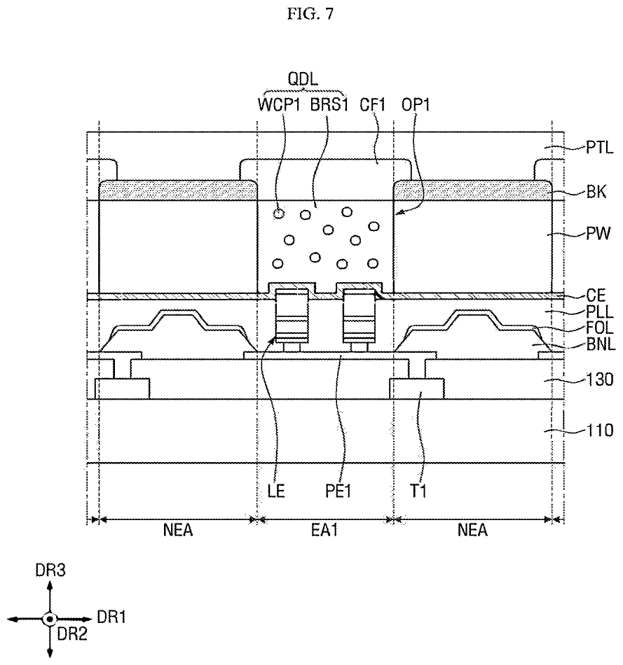

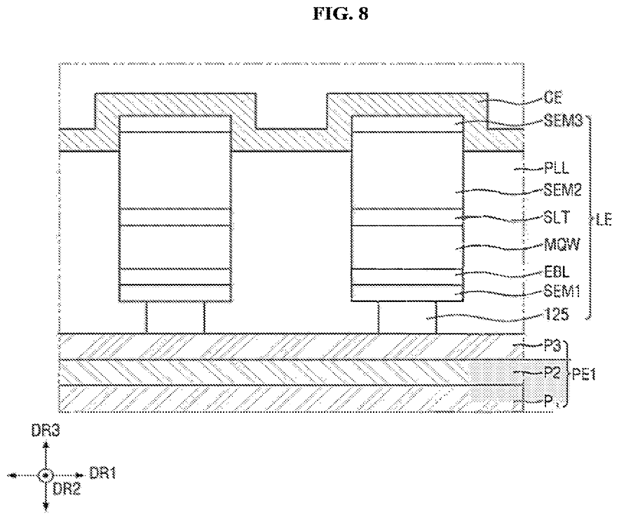

FIG. 6 is a cross-sectional view showing line A-A′ of FIG. 2 according to one or more embodiments. FIG. 7 is an enlarged view showing the first emission area of FIG. 6. FIG. 8 is a cross-sectional view showing in more detail the light-emitting diodes of FIG. 7.

Referring to FIGS. 6 to 8, the display panel of the display device 10 may include a display substrate 100 and a wavelength converting portion 200 provided on the display substrate 100.

A barrier layer BR may be provided on the first substrate 110 of the display substrate 100. The first substrate 110 may be made of an insulating material such as a polymer resin. For example, the first substrate 110 may be made of polyimide (PI). The first substrate 110 may be a flexible substrate that can be bent, folded, and/or rolled.

The barrier layer BR can protect thin-film transistors T1, T2 and T3 and a light-emitting diode portion LEP from moisture permeating through the first substrate 110 which is vulnerable to moisture permeation. The barrier layer BR may be formed of multiple inorganic layers stacked on one another alternately with each other. For example, the barrier layer BR may be made up of multiple layers in which one or more inorganic layers of a silicon nitride layer, a silicon oxynitride layer, a silicon oxide layer, a titanium oxide layer and/or an aluminum oxide layer are alternately stacked on one another.

The transistors T1, T2 and T3 may be provided on the barrier layer BR. Each of the thin-film transistors T1, T2 and T3 includes an active layer ACT1, ACT2, or ACT3, respectively, a gate electrode G1, G2, or G3, respectively, a source electrode S1, S2, or S3, respectively, and a drain electrode D1, D2, or D3, respectively.

The active layer ACT1, ACT2, or ACT3, respectively, the source electrode S1, S2, or S3, respectively, and the drain electrode D1, D2, or D3, respectively, of each of the thin-film transistors T1, T2 and T3 may be provided on the barrier layer BR. The active layer ACT1, ACT2, or ACT3, respectively, of each of the thin-film transistors T1, T2 and T3 may include polycrystalline silicon, single crystalline silicon, low-temperature polycrystalline silicon, amorphous silicon, and/or an oxide semiconductor. A part of the active layer ACT1, ACT2, or ACT3, respectively, overlapping the gate electrode G1, G2, or G3, respectively. in the third direction (z-axis direction) that is the thickness direction of the first substrate 110 may be defined as a channel region. The source electrode S1, S2, or S3, respectively, and the drain electrode D1, D2, or D3, respectively, are regions that do not overlap with the gate electrode G1, G2, or G3, respectively, in the third direction (z-axis direction), and may have conductivity by doping ions or impurities into a silicon semiconductor and/or an oxide semiconductor.

A gate insulator 130 may be provided on the active layer ACT1, ACT2, or ACT3, respectively, the source electrode S1, S2, or S3, respectively, and the drain electrode D1, D2, or D3, respectively, of each of the thin-film transistors T1, T2 and T3. The gate insulator 130 may be formed of an inorganic layer, for example, a silicon nitride layer, a silicon oxynitride layer, a silicon oxide layer, a titanium oxide layer, and/or an aluminum oxide layer.

The gate electrode G1, G2, or G3, respectively of each of the thin-film transistors T1, T2 and T3 may be provided on the gate insulator 130. The gate electrode G1, G2, or G3, respectively, may overlap the active layer ACT1, ACT2, or ACT3, respectively, in the third direction (z-axis direction). The gate electrode G1, G2, or G3, respectively, may be made up of a single layer or multiple layers of one of molybdenum (Mo), aluminum (Al), chromium (Cr), gold (Au), titanium (Ti), nickel (Ni), neodymium (Nd), copper (Cu), or an alloy thereof.

A first interlayer dielectric layer 141 may be provided on the gate electrode G1, G2, or G3, respectively of each of the thin-film transistors T1, T2 and T3. The first interlayer dielectric layer 141 may be formed of an inorganic layer, for example, a silicon nitride layer, a silicon oxynitride layer, a silicon oxide layer, a titanium oxide layer, and/or an aluminum oxide layer. The first interlayer dielectric layer 141 may be made of a plurality of inorganic layers.

A capacitor electrode CAE may be provided on the first interlayer dielectric layer 141. The capacitor electrode CAE may overlap the gate electrode G1, G2, or G3, respectively, of each of the thin-film transistors T1, T2 and T3 in the third direction (z-axis direction). Because the first interlayer dielectric layer 141 has a set or predetermined dielectric constant, a capacitor can be formed by the capacitor electrode CAE, the gate electrode G1, G2, or G3, respectively, and the first interlayer dielectric layer 141 provided between them. The capacitor electrode CAE may be made up of a single layer or multiple layers of one of molybdenum (Mo), aluminum (Al), chromium (Cr), gold (Au), titanium (Ti), nickel (Ni), neodymium (Nd), copper (Cu), or an alloy thereof.

A second interlayer dielectric layer 142 may be provided over the capacitor electrode CAE. The second interlayer dielectric layer 142 may be formed of an inorganic layer, for example, a silicon nitride layer, a silicon oxynitride layer, a silicon oxide layer, a titanium oxide layer, and/or an aluminum oxide layer. The second interlayer dielectric layer 142 may be made of a plurality of inorganic layers.

A first anode connection electrode ANDE1 may be provided on the second interlayer dielectric layer 142. The first anode connection electrode ANDE1 may be connected to the drain electrode D1, D2, or D3, respectively, of the thin-film transistor T1, T2, or T3, respectively, through a first connection contact hole ANCT1 that penetrates the gate insulator 130, the first interlayer dielectric layer 141 and the second interlayer dielectric layer 142. The first anode connection electrode ANDE1 may be made up of a single layer or multiple layers of one of molybdenum (Mo), aluminum (Al), chromium (Cr), gold (Au), titanium (Ti), nickel (Ni), neodymium (Nd), copper (Cu), or an alloy thereof.

A first planarization layer 160 may be provided over the first anode connection electrode ANDE1 for providing a flat surface over the thin-film transistors T1, T2 and T3 having different heights. The first planarization layer 160 may be formed of an organic layer such as an acryl resin, an epoxy resin, a phenolic resin, a polyamide resin and/or a polyimide resin.

A second anode connection electrode ANDE2 may be provided on the first planarization layer 160. The second anode connection electrode ANDE2 may be connected to the first anode connection electrode ANDE1 through a second connection contact hole ANCT2 penetrating the first planarization layer 160. The second anode connection electrode ANDE2 may be made up of a single layer or multiple layers of one of molybdenum (Mo), aluminum (Al), chromium (Cr), gold (Au), titanium (Ti), nickel (Ni), neodymium (Nd), copper (Cu), or an alloy thereof.

A second planarization layer 180 may be provided on the second anode connection electrode ANDE2. The second planarization layer 180 may be formed as an organic layer such as an acryl resin, an epoxy resin, a phenolic resin, a polyamide resin and/or a polyimide resin.

The light-emitting diode portion LEP may be formed on the second planarization layer 180. The light-emitting diode portion LEP may include a plurality of pixel electrodes PE1, PE2 and PE3, a plurality of light-emitting diodes LE, and a common electrode CE.

The plurality of pixel electrodes PE1, PE2 and PE3 may include a first pixel electrode PE1, a second pixel electrode PE2 and a third pixel electrode PE3. The first pixel electrode PE1, the second pixel electrode PE2 and the third pixel electrode PE3 may work as a first electrode of the light-emitting diodes LE and may be an anode electrode or a cathode electrode. The first pixel electrode PE1 may be provided in the first emission area EA1 and may be extended to the non-emission area NEA at least partially. The second pixel electrode PE2 may be provided in the second emission area EA2 and may be extended to the non-emission area NEA at least partially. The third pixel electrode PE3 may be provided in the third emission area EA3 and may be extended to the non-emission area NEA at least partially. The first pixel electrode PE1 may be connected to the first switching element (or thin-film transistor) T1 through the first anode connection electrode ANDE1 and the second anode connection electrode ANDE2, the second pixel electrode PE2 may be connected to the second switching element (or thin-film transistor) T2 through the first anode connection electrode ANDE1 and the second anode connection electrode ANDE2 130, and the third pixel electrode PE3 may be connected to the third switching element (or thin-film transistor) T3 through the first anode connection electrode ANDE1 and the second anode connection electrode ANDE2.

The first pixel electrode PE1, the second pixel electrode PE2 and the third pixel electrode PE3 may be reflective electrodes. The first pixel electrode PE1, the second pixel electrode PE2 and the third pixel electrode PE3 may be formed of titanium (Ti), copper (Cu), or an alloy of titanium (Ti) and copper (Cu). In some embodiments, they may have a stack structure of titanium (Ti) and copper (Cu). In some embodiments, the first pixel electrode PE1, the second pixel electrode PE2 and the third pixel electrode PE3 may have a structure of layers in which a material layer having a high work function, for example, TiO₂ (titanium oxide), ITO (indium tin oxide), IZO (indium zinc oxide), ZnO (zinc oxide), ITZO (indium tin zinc oxide) and/or MgO (magnesium oxide), and a reflective material layer of silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), titanium (Ti), copper (Cu), or a mixture thereof are stacked on one another. A material layer having a higher work function may be provided higher than a reflective material layer so that it may be closer to the light-emitting diode LE. The first pixel electrode PE1, the second pixel electrode PE2 and the third pixel electrode PE3 may have, but are not limited to, a multilayer structure of ITO/Mg, ITO/MgF, ITO/Ag, and/or ITO/Ag/ITO.

A bank BNL may be located on the first pixel electrode PE1, the second pixel electrode PE2 and the third pixel electrode PE3. The bank BNL may include an opening exposing the first pixel electrode PE1, an opening exposing the second pixel electrode PE2 and an opening exposing the third pixel electrode PE3, and may define the first emission area EA1, the second emission area EA2, the third emission area EA3 and the non-emission area NEA. For example, an area of the first pixel electrode PE1 that is not covered by the bank BNL and is exposed may be the first emission area EA1. An area of the second pixel electrode PE2 that is not covered by the bank BNL and is exposed may be the second emission area EA2. An area of the third pixel electrode PE3 that is not covered by the bank BNL and is exposed may be the third emission area EA3. The other area where the bank BNL is located may be the non-emission area NEA.

The bank BNL may include an organic insulating material, e.g., polyacrylate resin, epoxy resin, phenolic resin, polyamide resin, polyimide resin, unsaturated polyesters resin, poly phenylene ether resin, poly phenylene sulfide resin, and/or benzocyclobutene (BCB).

According to one or more embodiments of the present disclosure, the bank BNL may overlap color filters CF1, CF2 and CF3 of the wavelength converting portion 200 and a light-blocking member BK, which will be described in more detail herein below. According to one or more embodiments of the present disclosure, the bank BNL may completely overlap the light-blocking member BK. In one or more embodiments, the bank BNL may overlap the first color filter CF1, the second color filter CF2 and the third color filter CF3.

A plurality of light-emitting diodes LE may be provided on the first pixel electrode PE1, the second pixel electrode PE2 and the third pixel electrode PE3.

As shown in FIGS. 7 and 8, the light-emitting diodes LE may be provided in each of the first emission area EA1, the second emission area EA2 and the third emission area EA3. Each of the light-emitting diodes LE may be a vertical light-emitting diode extended in the third direction DR3. For example, the length of the light-emitting diodes LE in the third direction DR3 may be larger than the length in the horizontal direction. The horizontal length refers to either the length in the first direction DR1 or the length in the second direction DR2. For example, the length of the light-emitting diodes LE in the third direction DR3 may be approximately 1 to 5 μm.

The light-emitting diodes LE may be micro light-emitting diodes. The light-emitting diodes LE may include a connection electrode 125, a first semiconductor layer SEM1, an electron blocking layer EBL, an active layer MQW, a superlattice layer SLT, a second semiconductor layer SEM2 and a third semiconductor layer SEM3 in the thickness direction of the display substrate 100, e.g., in the third direction DR3. The connection electrode 125, the first semiconductor layer SEM1, the electron blocking layer EBL, the active layer MQW, the superlattice layer SLT, the second semiconductor layer SEM2 and the third semiconductor layer SEM3 may be stacked on one another in this order in the third direction DR3.

The light-emitting diodes LE may have a cylindrical shape, a disk shape, and/or a rod shape having the width smaller than the height. It should be understood, however, that the present disclosure is not limited thereto. The light-emitting diodes LE may have a shape of a rod, wire, tube, etc., a shape of a polygonal column such as a cube, a cuboid and/or a hexagonal column, or may have a shape extended in a direction with partially inclined outer surface.

The connection electrode 125 may be provided on each of the plurality of pixel electrodes PE1, PE2 and PE3. In the following description, the light-emitting diode LE provided on the first pixel electrode PE1 will be described as an example.

The connection electrode 125 may be in contact with the first contact electrode PE1 to apply an emission signal to the light-emitting diode LE. The connection electrode 125 may be an ohmic connection electrode. It is, however, to be understood that the present disclosure is not limited thereto. The connection electrodes 125 may be Schottky connection electrodes. The light-emitting diodes LE may include at least one connection electrode 125. Although each of the light-emitting diodes LE includes one connection electrode 125 in the example shown in FIGS. 7 and 8, the present disclosure is not limited thereto. In some embodiments, the light-emitting diodes LE may include a larger number of connection electrodes or may not include any. The following description on the light-emitting diodes LE may be equally applied even if the number of connection electrodes 125 is different or it further includes other structures.

The connection electrode 125 can reduce the resistance between the light-emitting diode LE and the first pixel electrode PE1 and can improve the adhesion therebetween when the light-emitting diode LE is electrically connected to the first pixel electrode PE1 in the display device 10 according to the embodiments of the present disclosure. The connection electrode 125 may include a metal oxide having conductivity. For example, the connection electrode 125 may be ITO. Because the connection electrode 125 is in direct contact with and connected to the first pixel electrode PE1 thereunder, it may be made of the same material as the first pixel electrode PE1. In one or more embodiments, the connection electrode 125 may optionally further include a reflective electrode made of a metal material having high reflectivity, such as aluminum (Al), and/or may include an anti-diffusion layer containing nickel (Ni). Accordingly, the adhesion between the connection electrode 125 and the first pixel electrode PE1 can be increased, so that the contact characteristic can be increased (and/or improved).

Referring to FIG. 8, in one or more other embodiments, the first pixel electrode PE1 may include a lower electrode layer P1, a reflective layer P2 and an upper electrode layer P3. The lower electrode layer P1 may be provided at the bottom of the first pixel electrode PE1 and may be electrically connected to the switching element (e.g., thin-film transistor). The lower electrode layer P1 may include a metal oxide, for example, titanium oxide (TiO₂), indium tin oxide (ITO), indium zinc oxide (IZO), zinc oxide (ZnO), indium tin zinc oxide (ITZO), and/or magnesium oxide (MgO).

The reflective layer P2 may be provided on the lower electrode layer P1 to reflect light emitted from the light-emitting LE upward. The reflective layer P2 may include a metal having a high reflectance, for example, silver (Ag), magnesium (Mg), aluminum (Al), platinum (Pt), lead (Pb), gold (Au), nickel (Ni), neodymium (Nd), iridium (Ir), chrome (Cr), lithium (Li), calcium (Ca), or a mixture thereof.

The upper electrode layer P3 may be provided on the reflective layer P2 and may be in direct contact with the light-emitting diode LE. The upper electrode layer P3 may be provided between the reflective layer P2 and the connection electrode 125 of the light-emitting diode LE, and may be in direct contact with the connection electrode 125. As described above, the connection electrode 125 may be made of a metal oxide, and the upper electrode layer P3 may also be made of a metal oxide like (e.g., same as) the connection electrode 125.

The first pixel electrode PE1, the second pixel electrode PE2 and the third pixel electrode PE3 may each independently be formed of titanium (Ti), copper (Cu), or an alloy of titanium (Ti) and copper (Cu). In one or more embodiments, the first pixel electrode PE1, the second pixel electrode PE2 and the third pixel electrode PE3 may each independently have a stack structure of titanium (Ti) and copper (Cu). The upper electrode layer P3 may include titanium oxide (TiO₂), indium tin oxide (ITO), indium zinc oxide (IZO), zinc oxide (ZnO), indium tin zinc oxide (ITZO), and/or magnesium oxide (MgO). According to one or more embodiments of the present disclosure, when the connection electrode 125 is made of ITO, the upper electrode layer P3 may be made up of a multi-layer structure of ITO/Ag/ITO.

The first semiconductor layer SEM1 may be provided on the connection electrode 125. The first semiconductor layer SEM1 may be p-type semiconductor, and may include a semiconductor material having the following chemical formula: AlₓGa_{y}In_{1-x-y}N (0≤x≤1, 0≤y≤1 and 0≤x+y+1). For example, it may be at least one of p-type doped AlGaInN, GaN, AlGaN, InGaN, AlN or InN. The first semiconductor layer SEM1 may be doped with a p-type dopant, and the p-type dopant may be Mg, Zn, Ca, Se, Ba, etc. For example, the first semiconductor layer SEM1 may be p-GaN doped with p-type Mg. The thickness of the first semiconductor layer SEM1 may be in a range, but is not limited to, from 30 nm to 200 nm.

The electron blocking layer EBL may be provided on the first semiconductor layer SEM1. The electron blocking layer EBL may suppress or reduce the flow of too many electrons into the active layer MQW. For example, the electron blocking layer EBL may be p-AlGaN doped with p-type Mg. The thickness of the electron blocking layer may be in a range of 10 nm to 50 nm, but the present disclosure is not limited thereto. In one or more embodiments, the electron blocking layer EBL may not be provided.

The active layer MQW may be provided on the electron blocking layer EBL. The active layer MQW may emit light as electron-hole pairs are combined therein in response to an electrical signal applied through the first semiconductor layer SEM1 and the second semiconductor layer SEM2.

The active layer MQW may include a material having a single or multiple quantum well structure. When the active layer MQW includes a material having the multiple quantum well structure, well layers and barrier layers may be alternately stacked on one another in the structure. The well layers may be made of InGaN, and the barrier layers may be made of GaN and/or AlGaN, but the present disclosure is not limited thereto. The thickness of the well layers may be approximately 1 nm to 4 nm, and the thickness of the barrier layers may be 3 nm to 10 nm.

In one or more embodiments, the active layer MQW may have a structure in which a semiconductor material having a large band gap energy and a semiconductor material having a small band gap energy are alternately stacked on one another, and may include other Group III to Group V semiconductor materials depending on the wavelength range of the emitted light. The light emitted by the active layer MQW is not limited to the first light. In some embodiments, the second light (light in the green wavelength range) or the third light (light in the red wavelength range) may be emitted by the active layer MQW.

For example, the color of the light emitted from the active layer MQW may vary depending on the content of indium (In). For example, as the content of indium (In) increases, the wavelength range of light output from the active layers may move to the red wavelength range, and as the content of indium (In) decreases, the wavelength range of the output light may move to the blue wavelength range. For example, when the content of indium (In) is equal to or less than 15%, the active layer MQW may emit the first light in the red wavelength band having a main peak wavelength in a range of approximately 600 nm to 750 nm. In other embodiments, when the content of indium (In) is 25%, the active layer MQW may emit the second light in the green wavelength band having a main peak wavelength in a range of approximately 480 nm to 560 nm. For example, when the content of indium (In) is equal to or greater than 35%, the active layer MQW may emit the third light in the blue wavelength band having a main peak wavelength in a range of approximately 370 nm to 460 nm. In the example shown in FIG. 6, the active layer MQW emits light in the blue wavelength band having a main peak wavelength of approximately 370 nm to 460 nm.

The superlattice layer SLT may be provided on the active layer MQW. The superlattice layer SLT may relieve or reduce stress between the second semiconductor layer SEM2 and the active layer MQW. For example, the superlattice layer SLT may be made of InGaN and/or GaN. The thickness of the superlattice layer SLT may be approximately 50 to 200 nm. In some embodiments, the superlattice layer SLT may not be provided.

The second semiconductor layer SEM2 may be provided on the superlattice layer SLT. The second semiconductor layer SEM2 may be an n-type semiconductor. The second semiconductor layer SEM2 may include a semiconductor material having the following chemical formula: AlₓGa_{y}In_{1-x-y}N (0≤x≤1, 0≤y≤1, 0≤x+y≤1). For example, it may be at least one of n-type doped AlGaInN, GaN, AlGaN, InGaN, AlN or InN. The second semiconductor layer SEM2 may be doped with an n-type dopant, and the n-type dopant may be Si, Ge, Sn, etc. For example, the second semiconductor layer SEM2 may be n-GaN doped with n-type Si. The thickness of the second semiconductor layer SEM2 may be in a range, but is not limited to, from 2 μm to 4 μm.

The third semiconductor layer SEM3 may be provided on the second semiconductor layer SEM2. The third semiconductor layer SEM3 may be provided between the second semiconductor layer SEM2 and the common electrode CE. The third semiconductor layer SEM3 may be an undoped semiconductor. The third semiconductor layer SEM3 may include the same material as the second semiconductor layer SEM2, but may not be doped with an n-type or p-type dopant. In one or more embodiments, the third semiconductor layer SEM3 may be, but is not limited to, at least one of undoped InAlGaN, GaN, AlGaN, InGaN, AlN, or InN.

A planarization layer PLL may be provided on the bank BNL and the plurality of pixel electrodes PE1, PE2 and PE3. The planarization layer PLL may provide a flat (or substantially flat) surface so that a common electrode CE, which will be described in more detail herein below, may be formed. The planarization layer PLL may be formed to have a set or predetermined height so that at least a part, for example, an upper portion of the plurality of light-emitting diodes LE, may protrude above the planarization layer PLL. For example, the height of the planarization layer PLL from the upper surface of the first pixel electrode PE1 may be less than the height of the light-emitting diodes LE.

The planarization layer PLL may include an organic material to provide a flat (or substantially flat) surface. For example, the planarization layer PLL may include polyacrylate resin, epoxy resin, phenolic resin, polyamide resin, polyimide resin, unsaturated polyesters resin, poly phenylene ether resin, poly phenylene sulfide resin, benzocyclobutene (BCB), etc.

The common electrode CE may be provided on the planarization layer PLL and the plurality of light-emitting diodes LE. For example, the common electrode CE may be provided on one surface of the first substrate 110 on which the light-emitting diodes LE are formed, and may be provided entirely on the display area DPA and the non-display area NDA. The common electrode CE may be provided to overlap the emission areas EA1, EA2 and EA3 in the display area DPA, and may have a suitably small thickness to allow light to exit.

The common electrode CE may be provided directly on upper and side surfaces of the plurality of light-emitting diodes LE. The common electrode CE may be in direct contact with the second semiconductor layer SEM2 and the third semiconductor layer SEM3 among side surfaces of the light-emitting diodes LE. As shown in FIG. 6, the common electrode CE may be a common layer that covers the plurality of light-emitting diodes LE and commonly connects the plurality of light-emitting diodes LE with one another. Because the conductive second semiconductor layer SEM2 has a patterned structure in each of the light-emitting diode LE, the common electrode CE may be in direct contact with the side surfaces of the second semiconductor layer SEM2 of each of the light-emitting diodes LE so that a common voltage can be applied to each of the light-emitting diode LE.

Because the common electrode CE is provided entirely on the first substrate 110 to apply the common voltage, the common electrode CE may include a material having a low resistance. In one or more embodiments, the common electrode CE may be formed to have a suitably small thickness to allow light to exit. For example, the common electrode CE may include a material having a low resistance, such as aluminum (Al), silver (Ag) and/or copper (Cu). The thickness of the common electrode CE may be, but is not limited to, approximately 10 Å to 200 Å.

Each of the above-described light-emitting diodes LE may receive a pixel voltage or an anode voltage from the pixel electrode through the connection electrode 125, and may receive a common voltage through the common electrode CE. The light-emitting diodes LE may emit light with a set or predetermined luminance according to a voltage difference between the pixel voltage and the common voltage.

According to one or more embodiments, by providing a plurality of light-emitting diodes LE, e.g., inorganic light-emitting diodes, on the pixel electrodes PE1, PE2 and PE3, it is possible to eliminate or reduce the disadvantages of organic light-emitting diodes, which are vulnerable to external moisture and/or oxygen, and to improve the lifetime and the reliability of the organic light-emitting diodes.

The first organic layer FOL may be provided on the bank BNL provided in the non-emission area NEA.

The first organic layer FOL may overlap with the non-emission area NEA but not with the emission areas EA1, EA2 and EA3. The first organic layer FOL may be provided directly on the bank BNL and may be spaced apart from a plurality of pixel electrodes PE1, PE2 and PE3 adjacent thereto. The first organic layer FOL may be provided entirely on the first substrate 110, and may surround the plurality of emission areas EA1, EA2 and EA3. The first organic layer FOL may be provided generally in a lattice shape.

The first organic layer FOL may serve to detach the plurality of light-emitting diodes LE in contact with the first organic layer FOL, which is the non-emission area NEA, as will be described with respect to the processing steps of fabricating the first organic layer FOL to be described herein below in more detail. When the first organic layer FOL is irradiated with laser light, it absorbs energy and its temperature is increased instantaneously, so that it is ablated. Accordingly, the plurality of light-emitting diodes LE in contact with the upper surface of the first organic layer FOL may be detached from the upper surface of the first organic layer FOL.

The first organic layer FOL may include a polyimide compound. The polyimide compound of the first organic layer FOL may include a cyano group to absorb light having the wavelength of 308 nm, for example, laser light. In one or more embodiments, each of the first organic layer FOL and the bank BNL may include a polyimide compound. The polyimide compound of one of them may be different from that of the other one. For example, the bank BNL may be formed of a polyimide compound not including a cyano group, whereas the first organic layer FOL may be formed of a polyimide compound including a cyano group. For laser light having the wavelength of 308 nm, the transmittance of the first organic layer FOL may be less than the transmittance of the bank BNL, for example, the transmittance of the bank BNL may be approximately 60% or more, and the transmittance of the first organic layer FOL may be 0%. The absorption rate of the first organic layer FOL with respect to the laser light having the wavelength of 308 nm may be 100%. The first organic layer FOL may have a thickness ranging from approximately 2 Å to 10 μm. When the thickness of the first organic layer FOL is 2 Å or more, the absorption rate of the laser light having the wavelength of 308 nm can be improved. When the thickness of the first organic layer FOL is 10 μm or less, it is possible to prevent or reduce the increase in the level difference between the first organic layer FOL and the pixel electrode PE1, so that the light-emitting diodes LE can be easily (or suitably) formed on the pixel electrode in a process to be described in more detail herein below.

The wavelength converting portion 200 may be provided on the light-emitting diode portion LEP. The wavelength converting portion 200 may include partition walls PW, wavelength conversion layers QDL, color filters CF1, CF2 and CF3, a light-blocking member BK, and a protective layer PTL.

The partition walls PW may be provided on the common electrode CE in the display area DPA, and may partition the plurality of emission areas EA1, EA2 and EA2 together with the bank BNL. The partition walls PW may be extended in the first direction DR1 and the second direction DR2, and may be formed in a lattice pattern throughout the entire display area DA. In one or more embodiments, the partition walls PW may not overlap the plurality of emission areas EA1, EA2 and EA3, and may overlap the non-emission area NEA.

The partition walls PW may include a plurality of openings OP1, OP2 and OP3 exposing the common electrode CE thereunder. The plurality of openings OP1, OP2 and OP3 may include a first opening OP1 overlapping the first emission area EA1, a second opening OP2 overlapping the second emission area EA2, and a third opening OP3 overlapping the third emission area EA3. The plurality of openings OP1, OP2 and OP3 may be in line with the plurality of emission areas EA1, EA2 and EA3, respectively. For example, the first opening OP1 may be in line with the first emission area EA1, the second opening OP2 may be in line with the second emission area EA2, and the third opening OP3 may be in line with the third emission area EA3.

The partition walls PW may provide a space where first and second wavelength conversion layers QDL1 and QDL2 can be formed. To this end, the partition walls PW may have a set or predetermined thickness, for example, the thickness of the partition wall PW may be in the range of 1 μm to 10 μm. The partition walls PW may include an organic insulating material to have a set or predetermined thickness. The organic insulating material may include, for example, an epoxy-based resin, an acrylic-based resin, a cardo-based resin, an imide-based resin, etc.

The first wavelength conversion layer QDL1 may be provided in each first opening OP1. The first wavelength conversion layer QDL1 may be formed in a pattern of dot-shaped islands spaced apart from one another. The first wavelength conversion layer QDL1 may include a first base resin BRS1 and first wavelength converting particles WCP1. The first base resin BRS1 may include a light-transmitting organic material. For example, the first base resin BRS1 may include an epoxy-based resin, an acrylic-based resin, a cardo-based resin, an imide-based resin, etc. The first wavelength converting particles WCP1 may be quantum dots (QD), quantum rods, fluorescent material, and/or phosphorescent material. For example, quantum dots may be particulate matter that emits a color as electrons transition from the conduction band to the valence band.

The quantum dots may be semiconductor nanocrystalline material. The quantum dots have a set or specific band gap depending on their compositions and size, and can absorb light and emit light having an intrinsic wavelength. Examples of the semiconductor nanocrystals of the quantum dots may include Group IV nanocrystals, Groups II-VI compound nanocrystals, Groups III-V compound nanocrystals, Groups IV-VI nanocrystals, and combinations thereof.

The first wavelength conversion layer QDL1 may be formed in the first opening OP1 of the first emission area EA1. The first wavelength conversion layer QDL1 may convert or shift the peak wavelength of the incident light into light of another peak wavelength. The first wavelength conversion layer QDL1 may convert some of the blue lights emitted from the light-emitting diodes LE into light of a color similar to red (e.g., a light in a red wavelength band), that is the first light. The first wavelength conversion layer QDL1 may output light of the color similar to red so that the light may be converted into red light, which is the first light, through the first color filter CF1.

The second wavelength conversion layer QDL2 may be provided in each second opening OP2. The second wavelength conversion layer QDL2 may be formed in a pattern of dot-shaped islands spaced apart from one another. For example, the second wavelength conversion layer QDL2 may overlap with the second emission area EA2. The second wavelength conversion layer QDL2 may include a second base resin BRS2 and second wavelength converting particles WCP2. The second base resin BRS2 may include a light-transmitting organic material. Accordingly, the second wavelength conversion layer QDL2 may convert or shift the peak wavelength of the incident light into light of another peak wavelength. The second wavelength conversion layer QDL2 may convert some of the blue lights emitted from the light-emitting diodes LE into light of a color similar to green (e.g., a light in a green wavelength band), that is the second light. The second wavelength conversion layer QDL2 may output light of the color similar to green (e.g., the light in a green wavelength band) so that the light may be converted into green light, which is the second light, through the second color filter CF2.

In the third emission area EA3, only a transparent, light-transmitting organic material is formed in the third opening OP3 (e.g., a wavelength conversion layer is not formed in the third opening OP3), and thus blue light emitted from the light-emitting diode LE can exit through the third color filter CF3 as it is.

The plurality of color filters CF1, CF2 and CF3 may be provided on the partition walls PW and the first and second wavelength conversion layers QDL1 and QDL2. The plurality of color filters CF1, CF2 and CF3 may overlap the plurality of openings OP1, OP2 and OP3 and the first and second wavelength conversion layers QDL1 and QDL2. The plurality of color filters CF1, CF2 and CF3 may include the first color filter CF1, the second color filter CF2 and the third color filter CF3.

The first color filter CF1 may overlap the first emission area EA1. In one or more embodiments, the first color filter CF1 may be provided on the first opening OP1 of the partition wall PW to overlap the first opening OP1. The first color filter CF1 may transmit the first light emitted from the light-emitting diodes LE and may absorb, block, or reduce the second light and the third light. For example, the first color filter CF1 may transmit light in the red wavelength range and may absorb, block, or reduce light in the green and blue wavelength ranges.

The second color filter CF2 may overlap the second emission area EA2. In one or more embodiments, the second color filter CF2 may be provided on the second opening OP2 of the partition wall PW to overlap the second opening OP2. The second color filter CF2 may transmit the second light and may absorb, block, or reduce the first light and the third light. For example, the second color filter CF2 may transmit light in the green wavelength range and may absorb, block, or reduce light in the blue and red wavelength ranges.

The third color filter CF3 may overlap the third emission area EA3. In one or more embodiments, the third color filter CF3 may be provided on the third opening OP3 of the partition wall PW to overlap the third opening OP3. The third color filter CF3 may transmit the third light and may absorb, block, or reduce the first light and the second light. For example, the third color filter CF3 may transmit light in the blue wavelength range and may absorb, block, or reduce light in the red and green wavelength ranges.

The area of the plurality of color filters CF1, CF2 and CF3 may be greater than the area of the plurality of emission areas EA1, EA2 and EA3 when viewed from the top. For example, the first color filter CF1 may have a larger area than the first emission area EA1 when viewed from the top. The second color filter CF2 may have a larger area than the second emission area EA2 when viewed from the top. The third color filter CF3 may have a larger area than the third emission area EA3 when viewed from the top. It should be understood, however, that the present disclosure is not limited thereto. The area of the plurality of color filters CF1, CF2 and CF3 may be equal to the area of the plurality of emission areas EA1, EA2 and EA3 when viewed from the top.

Referring to FIG. 6, the light-blocking member BK may be provided on the partition walls PW. The light-blocking member BK may overlap the non-emission area NEA to block or reduce transmission of light. The light-blocking member BK may be provided in a substantially lattice shape when viewed from the top, similar to the bank BNL or the partition walls PW. The light-blocking member BK may overlap the bank BNL, a first organic layer FOL and the partition wall PW, and may not overlap the emission areas EA1, EA2 and EA3.

According to one or more embodiments of the present disclosure, the light-blocking member BK may include an organic light-blocking material and may be formed via processes of coating and exposing the organic light-blocking material to light. The light-blocking member BK may include a dye or pigment having light-blocking properties, and may be a black matrix. At least a part of the light-blocking member BK may overlap adjacent color filters CF1, CF2 and CF3, and the color filters CF1, CF2 and CF3 may be provided on at least a part of the light-blocking member BK.

A first protection layer PTL may be provided on the plurality of color filters CF1, CF2 and CF3 and the light-blocking member BK. The first protection layer PTL may be provided at the top of the display device 10 to protect the plurality of color filters CF1, CF2 and CF3 and the light-blocking member BK. One surface, for example, the lower surface of the first protection layer PTL may be in contact with the plurality of color filters CF1, CF2 and CF3 and the upper surface of the light-blocking member BK.

The first protection layer PTL may include an inorganic insulating material to protect the plurality of color filters CF1, CF2 and CF3 and the light-blocking member BK. For example, the first protection layer PTL may include, but is not limited to, silicon oxide (SiOx), silicon nitride (SiNx), silicon oxynitride (SiOxNy), aluminum oxide (AlxOy), aluminum nitride (AlN), etc. The first protection layer PTL may have a set or predetermined thickness, for example, in a range of 0.01 to 1 μm. It is, however, to be understood that the present disclosure is not limited thereto.

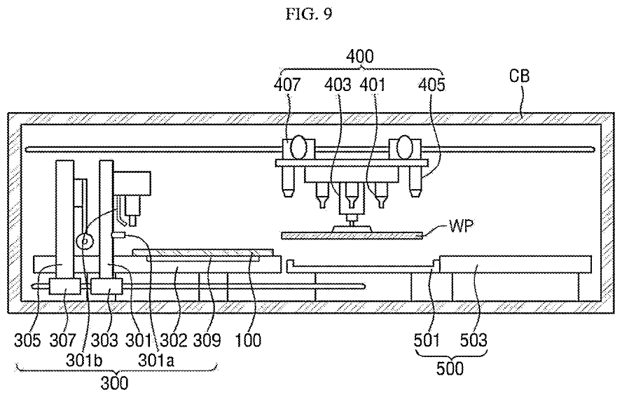

FIG. 9 is a side view showing an apparatus for fabricating a display panel according to one or more embodiments.

Referring to FIG. 9, an apparatus for fabricating a display panel includes a chamber CB, a first process driver 300, a second process driver 400, and a third process driver 500.

The chamber CB provides an internal processing space where processes are carried out, such as dispensing, coating, dipping, aligning, laminating, bonding, laser irradiating, and/or moving. The chamber CB may provide the processing space which is vacuum, can be heated up and cooled down, is soundproof, is vibration-free and is waterproof. To this end, the chamber CB may further include a vacuum device, an air suction device, a purification device, a heating device, a cooling device, etc.

The first process driver 300 includes a first loading unit 302, at least one dispenser 301, and at least one coating device 305.

The first loading unit 302 is provided at the lower portion on one side of the processing space inside the chamber CB. A pixel circuit substrate on which a plurality of pixel electrodes PE1, PE2 and PE3 are formed (hereinafter referred to as the display substrate 100) or a light-emitting diode substrate WP is loaded on the first loading unit 302. A cooling member or a heating member for cooling or heating the display substrate 100 or the light-emitting diode substrate WP may be further provided on at least one side or under the first loading unit 302. In one or more embodiments, a fixing member for aligning and fixing the display substrate 100 or the light-emitting diode substrate WP may be further provided on the front side of the first loading unit 302. An electronic scale 309 may be further provided on at least one side or the rear side of the first loading unit 302. The electronic scale 309 may measure and display in real time the dispensing capacity of an adhesive composition dispensed on the display substrate 100 or the light-emitting diode substrate WP relative to the weight of the display substrate 100 or the light-emitting diode substrate WP.

At least one dispenser 301 performs a dispensing process on the display substrate 100 or the light-emitting diode substrate WP loaded and fixed on the first loading unit 302. The at least one dispenser 301 may dispense an adhesion composition for improving adhesion between the display substrate 100 and the light-emitting diode LE, for example, an adhesion composition such as flux. The at least one dispenser 301 may be formed integrally with a dispenser moving member 303 moving along a set or predetermined path such as rails. The at least one dispenser 301 moves along the path of the dispenser moving member 303, and may dispense the adhesive composition onto the display substrate 100 or the light-emitting diode substrate WP loaded and fixed on the first loading unit 302.

The at least one dispenser 301 may further include at least one optical microscope 301a and at least one suction module 301b. The at least one optical microscope 301a is separately provided in a separate dispenser driver or dispenser fixing member, etc., and helps check at a high magnification a pattern formed on the display substrate 100 or the arrangement interval of the light-emitting diodes on the light-emitting diode substrate WP, etc. The at least one suction module 301b may be provided on one side of the dispenser 301 for dispensing an adhesive composition and/or the like to suck and/or clean residues of the dispenser 301.

The at least one coating device 305 performs a coating process on the display substrate 100 or the light-emitting diode substrate WP loaded and fixed on the first loading unit 302. Such at least one coating display device 305 may apply a physical force, for example, by rolling, to the adhesive composition dispensed on the display substrate 100 or the light-emitting diode substrate WP, so that the adhesive composition can be evenly (or substantially evenly) coated on the entire surface of the display substrate 100 or the light-emitting diode substrate WP.

The at least one coating device 305 may be formed integrally with a coating device moving member 307 moving along the same path as the dispenser moving member 303. The at least one coating device 305 may move along the path of the dispenser moving member 303 and may evenly (or substantially evenly) coat the adhesive composition dispensed on the display substrate 100 or the light-emitting diode substrate WP.

Because the dispenser moving member 303 and the coating device moving member 307 are arranged on the set or predetermined path such as rails depending on the arrangement structure of the first loading unit 302, the dispenser moving member 303 and the coating device moving member 307 may move sequentially on the same path. Accordingly, the at least one dispenser 301 and the at least one coating device 305 may sequentially move along the set or predetermined same path such as rails to sequentially perform dispensing and coating processes.

The dispenser moving member 303 and the coating device moving member 307 may be integrally formed on a set or predetermined path. Accordingly, the at least one dispenser 301 and the at least one coating device 305 may also be formed integrally with the dispenser moving member 303 or the coating device moving member 307, so that the dispensing and coating processes can be sequentially performed.

The second process driver 400 may be provided at the upper end or on one side of the processing space inside the chamber CB such that it can move along a set or predetermined path. The second process driver 400 is provided on a set or particular path such as rails inside the chamber CB to selectively perform processes such as moving, dipping, laminating, bonding and/or laser irradiating on the display substrate 100 or the light-emitting diode substrate WP on which the plurality of light-emitting diodes LE is arranged.

When dispensing and coating processes are performed on the display substrate 100 in the first process driver 300, the second process driver 400 may selectively perform processes such as moving, dipping, laminating, bonding and/or laser irradiating on the light-emitting diode substrate WP. In one or more embodiments, when dispensing and coating processes are performed on the light-emitting diode substrate WP in the first process driver 300, the second process driver 400 may selectively perform processes such as moving, dipping, laminating, bonding and/or laser irradiating on the display substrate 100.

The second process driver 400 includes a substrate laminating module 403, a module transfer mechanism 407, at least one camera module 405, and at least one laser module 401.

The substrate laminating module 403 adsorbs or holds the rear side of the display substrate 100 or the light-emitting diode substrate WP to vertically or horizontally move the display substrate 100 or the light-emitting diode substrate WP in the internal space of the chamber.

The substrate laminating module 403 adsorbs or holds the rear side of the light-emitting diode substrate WP to vertically move the light-emitting diode substrate WP in the internal space of the chamber CB, thereby laminating the light-emitting diode substrate WP with another display substrate 100 of the first process driver 300. In one or more embodiments, the substrate laminating module 403 may adsorb or hold the rear side of the display substrate 100 to laminate the display substrate 100 with another light-emitting diode substrate WP loaded onto the first process driver 300.

In one or more embodiments, once the display substrate 100 or the light-emitting diode substrate WP is loaded onto the third process driver 500, the substrate laminating module 403 may move another display substrate 100 or another light-emitting diode substrate WP to selectively laminate the display substrate 100 or the light-emitting diode substrate WP loaded on the third process driver 500.

The substrate laminating module 403 may perform a dipping process on the display substrate 100 or the light-emitting diode substrate WP. For example, to perform the dipping process on the display substrate 100 or the light-emitting diode substrate WP, the substrate laminating module 403 may vertically move the display substrate 100 or the light-emitting diode substrate WP in the internal space of the chamber CB and dip it in a dipping solution of the third process driver 500. In one or more embodiments, the substrate laminating module 403 may laminate the display substrate 100 or the light-emitting diode substrate WP after the dipping process with another display substrate 100 or another light-emitting diode substrate WP of the first process driver 300.

In one or more embodiments, the display substrate 100 or the light-emitting diode substrate WP may be loaded onto the third process driver 500. At this time, the substrate laminating module 403 may move the display substrate 100 or the light-emitting diode substrate WP to dip it into a dipping solution of the third process driver 500, and may laminate the dipped display substrate 100 or light-emitting diode substrate WP with another display substrate 100 or another light-emitting diode substrate WP loaded on the third process driver 500.

The module transfer mechanism 407 is movable along a set or predetermined path such as rails and moves the substrate laminating module 403 vertically or horizontally in the internal space of the chamber CB. The module transfer mechanism 407 and the substrate laminating module 403 may be formed integrally. The module transfer mechanism 407 may horizontally move the substrate laminating module 403 in the internal space of the chamber so that the substrate laminating module 403 can selectively laminate the display substrate 100 or the light-emitting diode substrate WP with another display substrate 100 or another light-emitting diode substrate WP of the first process driver 300 or the third process driver 500.

The at least one camera module 405 may be formed integrally with the substrate laminating module 403 or the module transfer mechanism 407, and may be moved horizontally or vertically together with the substrate laminating module 403 or the module transfer mechanism 407 in the internal space of the chamber CB.

The at least one camera module 405 aligns the display substrate 100 with the light-emitting diode substrate WP. To this end, the at least one camera module 405 detects alignment marks, alignment lines, image, etc. of the display substrate 100 and the light-emitting diode substrate WP that face each other and to be laminated together by the substrate laminating module 403. Then, the at least one camera module 405 transfers an error alignment signal based on comparison results of the detected alignment marks, alignment lines and image to the substrate laminating module 403 and the module transfer mechanism 407. Accordingly, the substrate laminating module 403 and the module transfer mechanism 407 may correct the horizontal position of the display substrate 100 or the light-emitting diode substrate WP according to the error alignment signal input from the at least one camera module 405, and may laminate the display substrate 100 with the light-emitting diode substrate WP.

The at least one laser module 401 may be formed integrally with the substrate laminating module 403 or the module transfer mechanism 407, and may be moved horizontally or vertically together with the substrate laminating module 403 or the module transfer mechanism 407 in the internal space of the chamber CB.

The at least one laser module 401 irradiates laser light to the laminated display substrate 100 and light-emitting diode substrate WP, so that the light-emitting diodes LE of the light-emitting diode substrate WP are attached to the pixel electrodes PE1, PE2 and PE3 of the display substrate 100. Accordingly, when the display substrate 100 is detached from the light-emitting diode substrate WP by the substrate laminating module 403, the light-emitting diodes LE remain attached to the pixel electrodes PE1, PE2 and PE3 of the display substrate 100.

The third process driver 500 is provided at the lower portion of the opposite side of the processing space inside the chamber CB so that the display substrate 100 or the light-emitting diode substrate WP is dipped and laminated. In one or more embodiments, the third process driver 500 includes at least one container 501 and at least one second loading unit 503.

The at least one container 501 may accommodate a dipping solution and may be provided below the second process driver 400. The at least one container 501 allows the display substrate 100 or the light-emitting diode substrate WP to be dipped in the dipping solution while it moves up and down by the second process driver 400. The dipping solution may include an adhesive composition such as flux.

The at least one second loading unit 503 allows the display substrate 100 or the light-emitting diode substrate WP to be loaded and fixed. Accordingly, the at least one second loading unit 503 allows the display substrate 100 or the light-emitting diode substrate WP dipped by the second process driver 400 to be laminated with the fixed light-emitting diode substrate WP or display substrate 100.

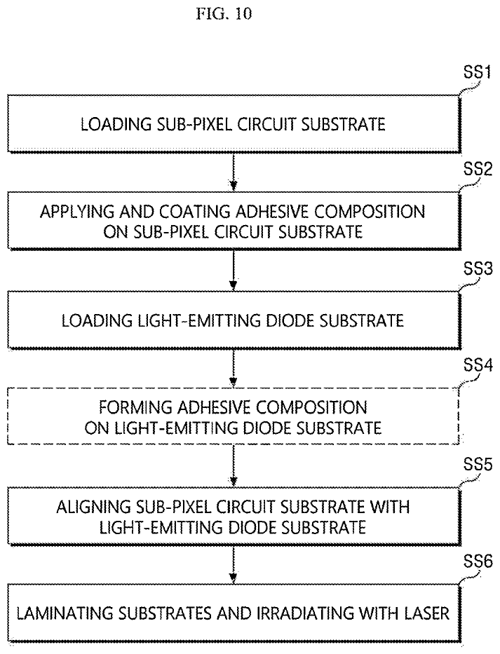

FIG. 10 is a flowchart for illustrating a method for fabricating a display panel using the apparatus of FIG. 9.

Referring to FIG. 10, the method for fabricating a display panel includes loading a display substrate 100 such as a sub-pixel circuit substrate, a wafer, or a light-emitting diode substrate WP on a first loading unit 302 of a first process driver 300 (step SS1); applying and coating an adhesive composition, etc. on the loaded display substrate 100 or light-emitting diode substrate WP (step SS2); loading another display substrate 100 or light-emitting diode substrate WP different from the substrate loaded on the first loading unit 302 onto a substrate laminating module 403 (step SS3); moving the substrate laminating module 403 to align the display substrate 100 or another light-emitting diode substrate WP on the display substrate 100 or the light-emitting diode substrate WP loaded on the first loading unit 302 (step SS5); and laminating the display substrate 100 or the light-emitting diode substrate WP of the first loading unit 302 with the display substrate 100 or the light-emitting diode substrate WP of the substrate laminating module 403 using the substrate laminating module 403 and irradiating with laser (step SS6). In doing so, an adhesive composition may be formed on the display substrate 100 or the light-emitting diode substrate WP loaded on the substrate laminating module 403 using the substrate laminating module 403 (step SS4), and the display substrate 100 or the light-emitting diode substrate WP of the substrate laminating module 403 may be aligned with the display substrate 100 or the light-emitting diode substrate WP loaded on the first loading unit 302 (step SS5).

A fixing member for aligning and fixing the display substrate 100 or the light-emitting diode substrate WP may be provided on the front side of the first loading unit 302. Accordingly, the display substrate 100 or the light-emitting diode substrate WP may be fixed on the first loading unit 302 by using the fixing member of the first loading unit 302 (step SS1).

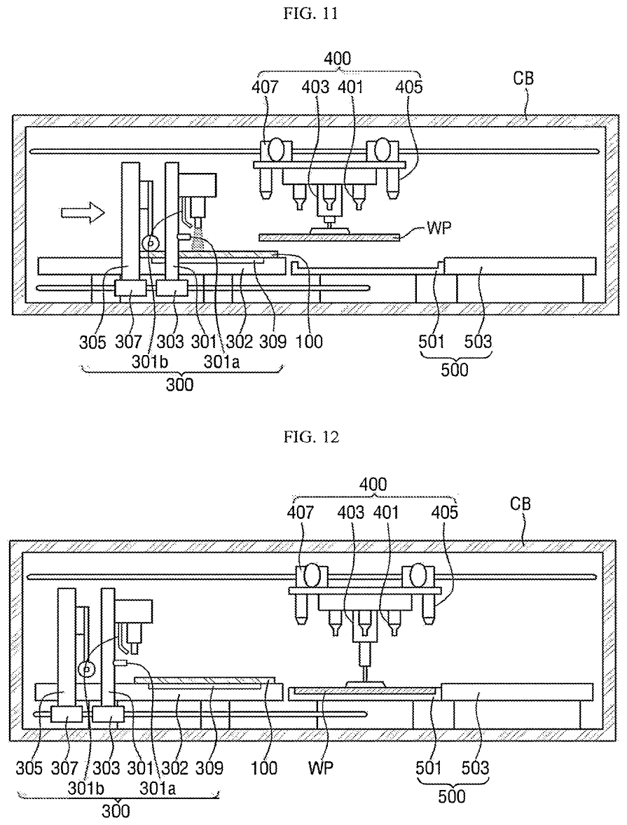

FIG. 11 is a side view showing a dispensing and coating process of a pixel circuit substrate using the apparatus of FIG. 9.

Referring to FIG. 11, an adhesive composition or the like may be applied to the display substrate 100 or the light-emitting diode substrate WP loaded on the first loading unit 302 and a coating process may be performed (step SS2).

The applying and coating SS2 the adhesive composition may include dispensing the adhesive composition onto the display substrate 100 or the light-emitting diode substrate WP loaded and fixed on the first loading unit 302 using the at least one dispenser 301 moving along the path of the dispenser moving member 303. Following the at least one dispenser 301, the at least one coating device 305 performs a coating process on the display substrate 100 or the light-emitting diode substrate WP loaded and fixed on the first loading unit 302.

The at least one coating device 305 may evenly (or substantially evenly) coat the dispensed adhesive composition on the display substrate 100 or the light-emitting diode substrate WP while moving along the path of the dispenser moving member 303.

Because the dispenser moving member 303 and the coating device moving member 307 are arranged on the set or predetermined path such as rails depending on the arrangement structure of the first loading unit 302, the dispenser moving member 303 and the coating device moving member 307 may move sequentially on the same path. Accordingly, the at least one dispenser 301 and the at least one coating device 305 may sequentially move along the set or predetermined same path such as rails to sequentially perform dispensing and coating processes.

The substrate laminating module 403 may adsorb or hold the rear side of another light-emitting diode substrate WP different from the display substrate 100 loaded on the first loading unit 302 (step SS3).

The module transfer mechanism 407 for moving the substrate laminating module 403 is movable along the set or predetermined path such as rails, and moves the substrate laminating module 403 vertically or horizontally in the internal space of the chamber CB.

The substrate laminating module 403 may move vertically and horizontally while adsorbing or holding the rear side of the light-emitting diode substrate WP, and may align the light-emitting diode substrate WP with the display substrate 100 loaded on the first loading unit 302 (step SS5). In one or more embodiments, the substrate laminating module 403 may adsorb or hold the rear side of the display substrate 100 to align the display substrate 100 with another light-emitting diode substrate WP loaded onto the first process driver 300 (step SS5).

Once the light-emitting diode substrate WP is aligned with the display substrate 100 of the first loading unit 302, the substrate laminating module 403 may move the light-emitting diode substrate WP vertically to laminate the display substrate 100 with the light-emitting diode substrate WP. Subsequently, a laser may be irradiated onto the display substrate 100 and the light-emitting diode substrate WP thus laminated (step SS6).

The module transfer mechanism 407 and the substrate laminating module 403 may be formed integrally. The module transfer mechanism 407 may horizontally move the substrate laminating module 403 in the internal select of the chamber so that the substrate laminating module 403 can selectively laminate the display substrate 100 or the light-emitting diode substrate WP with another display substrate 100 or another light-emitting diode substrate WP of the first process driver 300 or the third process driver 500.

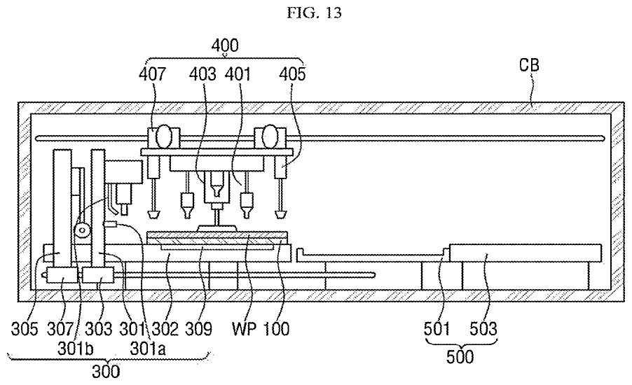

FIG. 12 is a side view showing a dipping process of a light-emitting diode substrate using the apparatus of FIG. 9.

As shown in FIG. 12, a dipping process on the display substrate 100 or the light-emitting diode substrate WP may be carried out using the substrate laminating module 403 (step SS4). At this time, the substrate laminating module 403 may perform a dipping process on the display substrate 100 or the light-emitting diode substrate WP. For example, to perform the dipping process on the display substrate 100 or the light-emitting diode arrangement substrate WP, the substrate laminating module 403 may vertically move the display substrate 100 or the light-emitting diode arrangement substrate WP in the internal space of the chamber CB and dip it in a dipping solution of the third process driver 500. In one or more embodiments, the substrate laminating module 403 may laminate the display substrate 100 or the light-emitting diode arrangement substrate WP after the dipping process with another display substrate 100 or another light-emitting diode arrangement substrate WP of the first process driver 300.

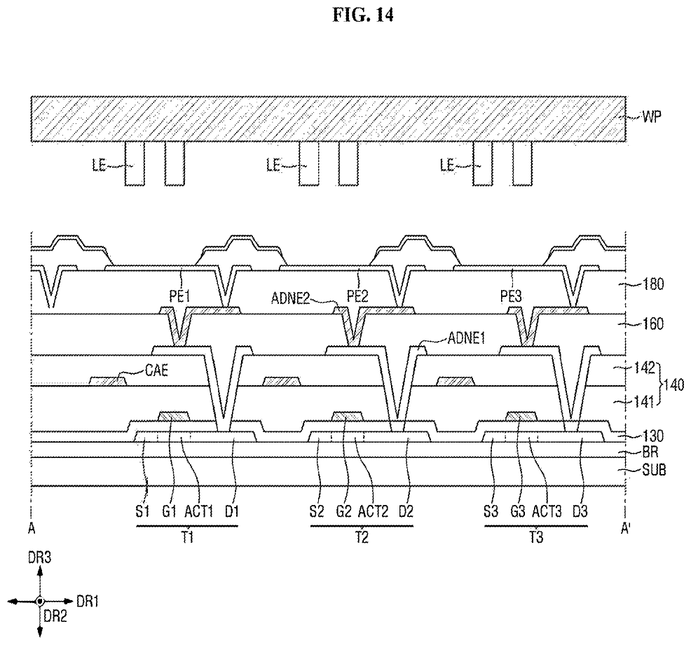

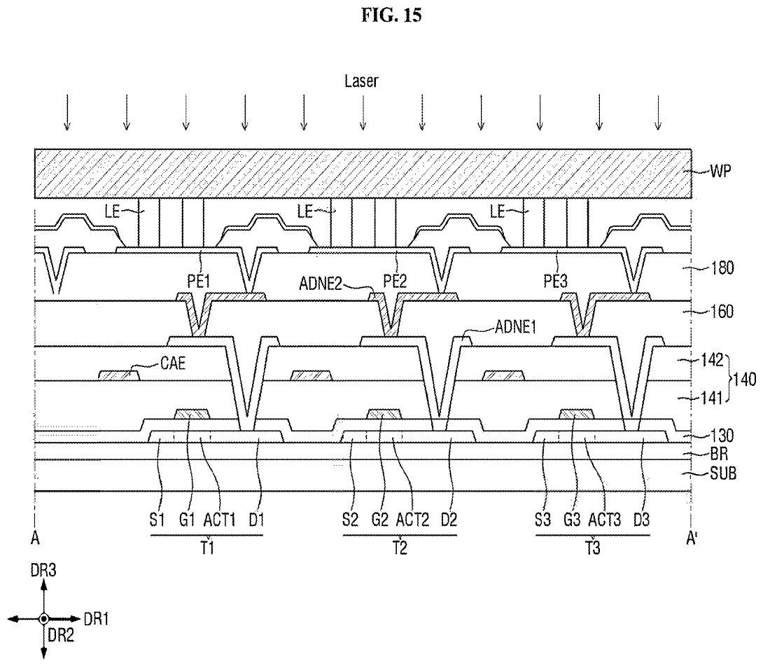

FIG. 13 is a side view showing a process of laminating a pixel circuit substrate with a light-emitting diode substrate using the apparatus of FIG. 9. FIGS. 14 to 16 are cross-sectional views of a pixel circuit substrate for illustrating a process of attaching light-emitting diodes to the pixel circuit substrate by the apparatus of FIG. 9.

Referring to FIGS. 14 to 16 in conjunction with FIG. 13, another display substrate 100 or another light-emitting diode substrate WP is arranged with the display substrate 100 or the light-emitting diode substrate WP using the substrate laminating module 403, and then they may be sequentially laminated (step SS5).

The substrate laminating module 403 adsorbs or holds the rear side of the light-emitting diode arrangement substrate WP to vertically move the light-emitting diode arrangement substrate WP in the internal space of the chamber CB, thereby laminating the light-emitting diode arrangement substrate WP with another display substrate 100 of the first process driver 300.

The camera module 405 aligns the display substrate 100 with the light-emitting diode substrate WP during the alignment process. In doing so, the at least one camera module 405 detects alignment marks, alignment lines, image, etc. of the display substrate 100 and the light-emitting diode arrangement substrate WP that face each other and to be laminated together by the substrate laminating module 403. Then, the at least one camera module 405 transfers an error alignment signal based on comparison results of the detected alignment marks, alignment lines and image to the substrate laminating module 403 and the module transfer mechanism 407. Accordingly, the substrate laminating module 403 and the module transfer mechanism 407 may correct the horizontal position of the display substrate 100 or the light-emitting diode arrangement substrate WP according to the error alignment signal input from the at least one camera module 405, and may laminate the display substrate 100 with the light-emitting diode arrangement substrate WP.

The laser module 401 irradiates a laser to the display substrate 100 and the light-emitting diode substrate WP to attach and fix the light-emitting diodes LE to the display substrate 100 (step SS6).

The laser module 401 irradiates laser light to the laminated display substrate 100 and light-emitting diode arrangement substrate WP, so that the light-emitting diodes LE of the light-emitting diode arrangement substrate WP are attached to the pixel electrodes PE1, PE2 and PE3 of the display substrate 100. Accordingly, when the display substrate 100 is detached from the light-emitting diode substrate WP by the substrate laminating module 403, the light-emitting diodes LE remain attached to the pixel electrodes PE1, PE2 and PE3 of the display substrate 100. For example, when the display substrate 100 is detached from the light-emitting diode substrate WP by the substrate laminating module 403, the light-emitting diodes LE remain attached to the pixel electrodes PE1, PE2 and PE3 of the display substrate 100.

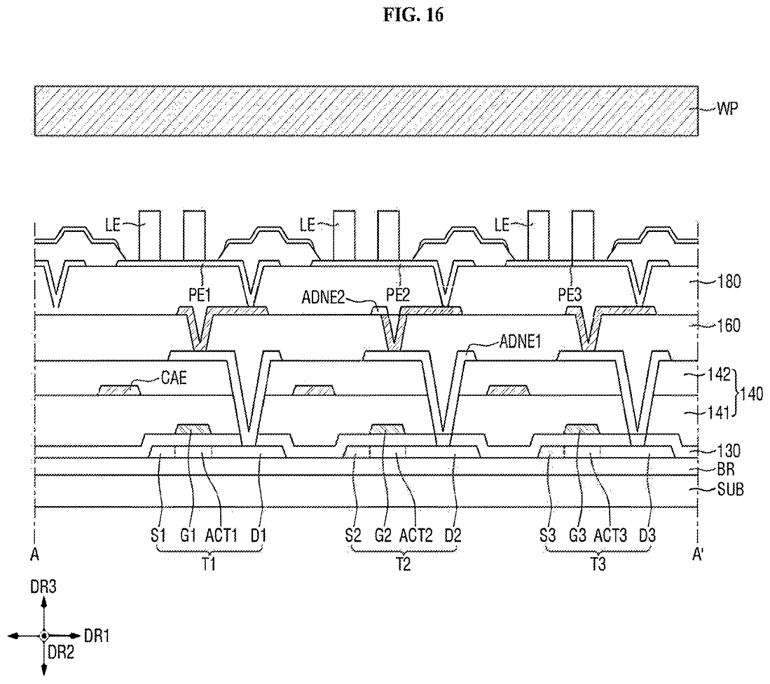

FIG. 17 is another flowchart for illustrating a method for fabricating a display panel using the apparatus of FIG. 9.

Referring to FIG. 17, the method for fabricating a display panel further includes loading the light-emitting diode substrate WP or the display substrate 100 onto the substrate laminating module 403 of the second process driver 400 (step ST1); forming an adhesive composition on the light-emitting diode substrate WP or the display substrate 100 loaded on the substrate laminating module 403 (step ST2); loading another display substrate 100 or another light-emitting diode substrate WP different from the light-emitting diode substrate WP or the display substrate 100 loaded on the substrate laminating module 403 onto the second loading unit 503 of the third process driver 500 (step ST3); aligning the light-emitting diode substrate WP or the display substrate 100 of the substrate laminating module 403 on another display substrate 100 or another light-emitting diode substrate WP loaded on the second loading unit 503 (step ST4); and laminating another display substrate 100 or another light-emitting diode substrate WP loaded on the second loading unit 503 with the light-emitting diode substrate WP or the display substrate 100 of the substrate laminating module 403 and irradiating with a laser (step ST5).

Once the display substrate 100 or the light-emitting diode substrate WP is loaded onto the third process driver 500, the substrate laminating module 403 may move another display substrate 100 or another light-emitting diode substrate WP to selectively laminate the display substrate 100 or the light-emitting diode substrate WP loaded on the third process driver 500. To this end, the substrate laminating module 403 adsorbs or holds the rear side of the light-emitting diode substrate WP or the display substrate 100 and moves the light-emitting diode substrate WP or the display substrate 100 vertically in the internal space of the chamber CB (step ST1).

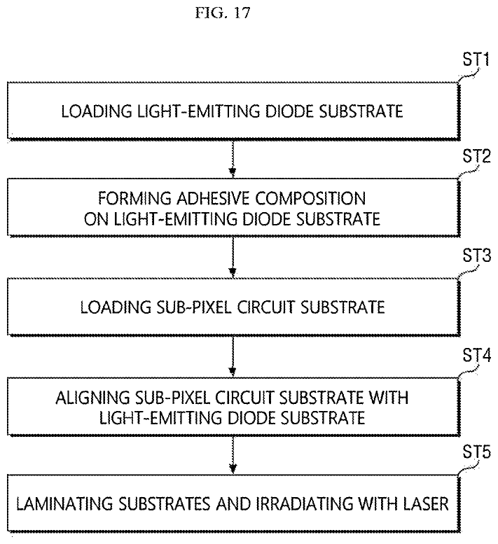

FIG. 18 is another side view showing a dipping process of a light-emitting diode substrate using the apparatus of FIG. 9.

Referring to FIG. 18, the substrate laminating module 403 may perform a dipping process to form an adhesive composition on the display substrate 100 or the light-emitting diode substrate WP.

To perform the dipping process on the display substrate 100 or the light-emitting diode arrangement substrate WP, the substrate laminating module 403 may vertically move the display substrate 100 or the light-emitting diode arrangement substrate WP in the internal space of the chamber CB and dip it in a dipping solution of the third process driver 500. In one or more embodiments, the substrate laminating module 403 may laminate the display substrate 100 or the light-emitting diode arrangement substrate WP after the dipping process with another display substrate 100 or another light-emitting diode substrate WP of the third process driver 500.

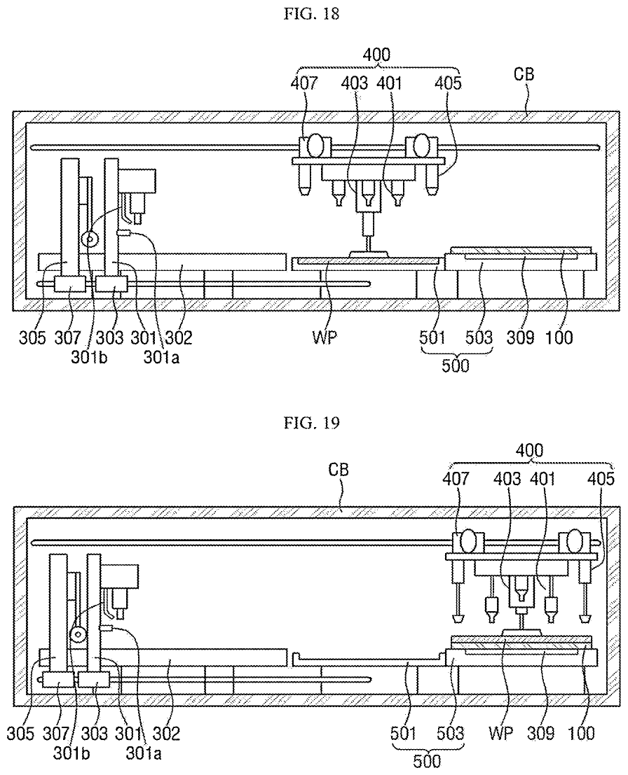

FIG. 19 is another side view showing a process of laminating a pixel circuit substrate with a light-emitting diode substrate using the apparatus of FIG. 9.

Referring to FIG. 19, when the display substrate 100 or the light-emitting diode substrate WP is loaded onto the third process driver 500 (step ST3), the light-emitting diode substrate WP or the display substrate 100 of the substrate laminating module 403 is aligned with the display substrate 100 or the light-emitting diode substrate WP loaded on the second loading unit 503 (step ST4). At this time, at least one camera module 405 aligns the display substrate 100 or the light-emitting diode substrate WP.

Subsequently, the substrate laminating module 403 may move the dipped light-emitting diode substrate WP or the display substrate 100 to be laminated with the display substrate 100 or the light-emitting diode substrate WP loaded on the third process driver 500. Then, the laser module 401 irradiates laser light to the display substrate 100 and light-emitting diode substrate WP thus laminated, so that the light-emitting diodes LE of the light-emitting diode substrate WP are attached to the pixel electrodes PE1, PE2 and PE3 of the display substrate 100. For example, when the display substrate 100 is detached from the light-emitting diode substrate WP by the substrate laminating module 403, the light-emitting diodes LE remain attached to the pixel electrodes PE1, PE2 and PE3 of the display substrate 100.

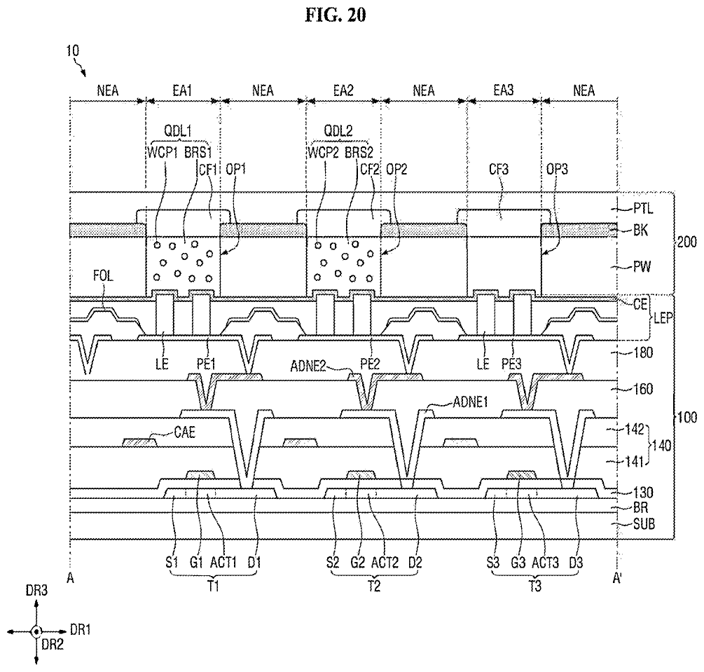

FIG. 20 is a cross-sectional view of a pixel circuit substrate for illustrating a process of fabricating a pixel circuit substrate after the arrangement of light-emitting diodes.

As shown in FIG. 20, a wavelength converting portion 200 may be provided on a light-emitting diode portion LEP where light-emitting diodes LE are provided. The wavelength converting portion 200 may include partition walls PW, wavelength conversion layers QDL, color filters CF1, CF2 and CF3, a light-blocking member BK, and a protective layer PTL.

The protective layer PTL may be provided on a plurality of color filters CF1, CF2 and CF3 and the light-blocking member BK to protect the plurality of color filters CF1, CF2 and CF3 and the light-blocking member BK thereunder.

According to the above-described embodiments of the present disclosure, the apparatus for fabricating a display panel allows for the light-emitting diode substrate WP and the circuit substrate of the display panel to be selectively pre-processed in the same space inside a single chamber CB, and for the substrates to be laminated, so that the time and cost for fabricating the display panel can be saved or reduced.

In one or more embodiments, fabrication processes may be carried out such as dispensing, coating, dipping, aligning, laminating, bonding, laser irradiating and/or moving on each substrate in the same space inside a single chamber CB. Accordingly, it is possible to reduce the fabrication space and increase the fabrication efficiency.

In concluding the detailed description, those skilled in the art will appreciate that many variations and modifications can be made to the embodiments without substantially departing from the principles of the present disclosure as set forth in the following claims and their equivalents. Therefore, the disclosed embodiments of the present disclosure are used in a generic and descriptive sense only and not for purposes of limitation.

What is claimed is:

1. An apparatus for fabricating a display panel, the apparatus comprising:
a chamber;
a first process driver configured to sequentially perform a dispensing process and a coating process on a display substrate or a light-emitting diode substrate in an internal processing space of the chamber;
a second process driver configured to selectively perform at least one process selected from among a moving process, a dipping process, a laminating process, a bonding process, and a laser irradiating process on the display substrate or the light-emitting diode substrate; and
a third process driver where at least one selected from the dipping and laminating processes is performed on the display substrate or the light-emitting diode substrate.

2. The apparatus of claim 1, wherein the first process driver comprises:
a first loading unit at a lower portion of the internal processing space inside the chamber, the display substrate or the light-emitting diode substrate being configured to be loaded on the first loading unit;
at least one dispenser configured to perform the dispensing process on the display substrate or the light-emitting diode substrate loaded on the first loading unit; and
at least one coating device configured to perform the coating process on the display substrate or the light-emitting diode substrate.

3. The apparatus of claim 2, wherein the at least one dispenser and the at least one coating device are on a same set path in the internal processing space inside the chamber and are configured to sequentially move along the path to sequentially perform the dispensing process and the coating process.

4. The apparatus of claim 2, wherein the at least one dispenser is formed integrally with a dispenser moving member that is configured to move along a set path in the internal processing space inside the chamber, and
the at least one dispenser is configured to perform the dispensing process on the display substrate or the light-emitting diode substrate loaded on the first loading unit while moving along the path of the dispenser moving member.

5. The apparatus of claim 4, wherein the at least one coating device is formed integrally with a coating device moving member that is configured to move along a same path as the dispenser moving member, and
the at least one coating device is configured to perform the coating process on the display substrate or the light-emitting diode substrate while moving along the path of the coating device moving member.

6. The apparatus of claim 5, wherein the dispenser moving member and the coating device moving member are integrally formed on a set path in the internal processing space inside the chamber, and
wherein the at least one dispenser and the at least one coating device are formed integrally with the dispenser moving member and the coating device moving member, respectively, to sequentially perform the dispensing process and the coating process.

7. The apparatus of claim 1, wherein the second process driver is configured to be movable along a predetermined path at an upper portion of the internal processing space inside the chamber, and
wherein the second process driver is configured to selectively perform the at least one process selected from among a moving process, a dipping process, a laminating process, a bonding process, and a laser irradiating process with respect to a display substrate or a light-emitting diode substrate different from the display substrate or the light-emitting diode substrate on which the dispensing process and the coating process are performed in the first process driver.

8. The apparatus of claim 7, wherein the second process driver comprises:
a substrate laminating module configured to hold a rear side of the display substrate or the light-emitting diode substrate to vertically or horizontally move the display substrate or the light-emitting diode substrate in the internal processing space inside the chamber;
a module transfer mechanism configured to vertically or horizontally move the substrate laminating module along a predetermined path in the internal processing space inside the chamber;
at least one camera module formed integrally with the substrate laminating module or the module transfer mechanism and configured to align the display substrate with the light-emitting diode substrate; and
at least one laser module formed integrally with the substrate laminating module or the module transfer mechanism and configured to irradiate laser light to the display substrate and the light-emitting diode substrate laminated together.

9. The apparatus of claim 8, wherein the substrate laminating module is configured to laminate the display substrate or the light-emitting diode substrate with the display substrate or the light-emitting diode substrate loaded on the first process driver or another display substrate or another light-emitting diode substrate loaded on the third process driver.

10. The apparatus of claim 8, wherein the substrate laminating module is configured to vertically move the display substrate or the light-emitting diode substrate in the internal processing space inside the chamber to dip the display substrate or the light-emitting diode substrate in a dipping solution of the third process driver, and to laminate the display substrate or the light-emitting diode substrate after the dipping process with another display substrate or another light-emitting diode substrate loaded on the first process driver.

11. The apparatus of claim 8, wherein the substrate laminating module is configured to vertically move the display substrate or the light-emitting diode substrate in the internal processing space inside the chamber to dip the display substrate or the light-emitting diode substrate in a dipping solution of the third process driver, and to laminate the display substrate or the light-emitting diode substrate after the dipping process with another display substrate or another light-emitting diode substrate loaded on the third process driver.

12. The apparatus of claim 2, wherein the third process driver comprises:
a container configured to accommodate a dipping solution in which the display substrate or the light-emitting diode substrate is to configured be dipped by the second process driver; and
a second loading unit where another display substrate or another light-emitting diode substrate is configured to be loaded and fixed, and where the display substrate or the light-emitting diode substrate dipped by the second process driver is configured to be laminated with the other display substrate or the other light-emitting diode substrate loaded and fixed in the second loading unit.

13. A method for fabricating a display panel, the method comprising:
loading a display substrate or a light-emitting diode substrate onto a first loading unit of a first process driver in a chamber;
performing a dispensing process and a coating process on the display substrate or the light-emitting diode substrate loaded on the first loading unit;
moving another display substrate or another light-emitting diode substrate via a second process driver in the chamber;
aligning and laminating the other display substrate or the other light-emitting diode substrate with the display substrate or the light-emitting diode substrate loaded on the first loading unit to form a laminate structure comprising one display substrate and one light-emitting diode substrate; and
attaching and fixing light-emitting diodes to the one display substrate of the laminate structure by irradiating a laser to the laminate structure.

14. The method of claim 13, wherein the performing the dispensing process and the coating process comprises:
dispensing an adhesive composition onto the display substrate or the light-emitting diode substrate loaded on the first loading unit via at least one dispenser at a lower portion on one side of a processing space inside the chamber; and
performing the coating process on the display substrate or the light-emitting diode substrate via at least one coating device.

15. The method of claim 14, wherein the performing the coating process comprises performing the coating process on the display substrate or the light-emitting diode substrate while moving the at least one coating device in a same path as the at least one dispenser.

16. The method of claim 14, wherein the performing the dispensing process and the coating process comprises:
sequentially performing the dispensing process and the coating process while concurrently moving the at least one dispenser and the at least one coating device, the at least one dispenser being formed integrally with a dispenser moving member.

17. The method of claim 13, wherein the aligning and laminating the other display substrate or the other light-emitting diode substrate with the display substrate or the light-emitting diode substrate loaded onto the first loading unit comprises:
moving the other display substrate or the other light-emitting diode substrate vertically or horizontally in the internal processing space inside the chamber;
aligning the display substrate and the other light-emitting diode substrate, or aligning the light-emitting diode substrate and the other display substrate, using at least one camera module; and
laminating the display substrate or the light-emitting diode substrate with the other light-emitting diode substrate or the other display substrate, respectively, and irradiating laser light with at least one laser module.

18. The method of claim 13, further comprising:
performing a dipping process on the other display substrate or the other light-emitting diode substrate via the second process driver; and
laminating the dipped display substrate or the dipped light-emitting diode substrate with the corresponding display substrate or the corresponding light-emitting diode substrate loaded on the first loading unit.

19. The method of claim 13, further comprising:
performing a dipping process on the other display substrate or the other light-emitting diode substrate via the second process driver;
loading the display substrate or the light-emitting diode substrate onto a second loading unit of a third process driver;
laminating the dipped display substrate or the dipped light-emitting diode substrate with the display substrate or the light-emitting diode substrate loaded onto the second loading unit to form a laminate structure comprising one display substrate and one light-emitting diode substrate; and
attaching and fixing light-emitting diodes to the one display substrate of the laminate structure by irradiating a laser onto the laminate structure.

20. The method of claim 19, wherein the aligning and laminating the other display substrate or the other light-emitting diode substrate with the display substrate or the light-emitting diode substrate loaded onto the second loading unit comprises:
aligning the display substrate loaded onto the second loading unit with the dipped light-emitting diode substrate using at least one camera module; and
laminating the display substrate with the dipped light-emitting diode substrate and irradiating laser light with at least one laser module.
